(19) United States
(12) Patent Application Publication
(10) Pub. No.: US 2025/0126801 A1
(43) Pub. Date: Apr. 17, 2025

(54) SEMICONDUCTOR MEMORY DEVICE

(71) Applicant: SAMSUNG ELECTRONICS CO., LTD., Suwon-si (KR)

(72) Inventors: Ju Seong Min, Suwon-si (KR); Hak Seon Kim, Suwon-si (KR); Jae-Bok Baek, Suwon-si (KR); Kang-Oh Yun, Suwon-si (KR); Taek Kyu Yoon, Suwon-si (KR); Dong Jin Lee, Suwon-si (KR); Jae Duk Lee, Suwon-si (KR); Se Jin Lim, Suwon-si (KR); Jee Hoon Han, Suwon-si (KR)

(21) Appl. No.: 18/732,848

(22) Filed: Jun. 4, 2024

(30) Foreign Application Priority Data
Oct. 12, 2023 (KR) 10-2023-0135810

(51) Int. Cl. H10B 43/40; H10B 43/27

(52) U.S. Cl. CPC H10B 43/40; H10B 43/27

(57) ABSTRACT

The present disclosure relates to semiconductor memory devices. An example semiconductor memory device includes a cell region and a peripheral circuit region electrically connected with the cell region. The cell region includes a plurality of gate electrodes spaced apart from each other and stacked in a vertical direction, and a channel structure extending through the plurality of gate electrodes in the vertical direction. The peripheral circuit region includes a substrate, a first element isolation structure, a first gate structure on the first active region, a second element isolation structure, a second gate structure on the second active region, a third element isolation structure, and a third gate structure on the third active region. The third element isolation structure includes a first element isolation pattern and a second element isolation pattern. The first element isolation pattern and the second element isolation pattern include different materials from each other.

### CROSS-REFERENCE TO RELATED APPLICATION

This application claims the benefit of Korean Patent Application No. 10-2023-0135810, filed on Oct. 12, 2023, in the Korean Intellectual Property Office, the disclosure of which is incorporated herein in its entirety by reference.

### BACKGROUND

In an electronic system that requires a data storage, there is a need for semiconductor elements that may store high-capacity data. Accordingly, methods capable of increasing the data storage capacity of the semiconductor elements are being researched. For example, as one method for increasing the data storage capacity of the semiconductor element, semiconductor elements including memory cells arranged three-dimensionally instead of memory cells arranged two-dimensionally are proposed.

### SUMMARY

The present disclosure relates to semiconductor memory devices, including a semiconductor memory device having improved performance and reliability.

However, the present disclosure are not restricted to the one set forth herein. The above and other aspects of the present disclosure will become more apparent to one of ordinary skill in the art to which the present disclosure pertains by referencing the detailed description of the present disclosure given below.

In some implementations, a semiconductor memory device includes a cell region; and a peripheral circuit region electrically connected to the cell region, in which the cell region includes a plurality of gate electrodes which are spaced apart from each other and stacked in a vertical direction, and a channel structure which penetrates the plurality of gate electrodes in the vertical direction, in which the peripheral circuit region includes a substrate, a first element isolation structure which defines a first active region in the substrate and extends to a first depth, a first gate structure placed on the first active region, a second element isolation structure which defines a second active region in the substrate, and extends to a second depth deeper than the first depth, a second gate structure placed on the second active region, a third element isolation structure which defines a third active region on the substrate, and includes a first element isolation pattern extending to a third depth, and a second element isolation pattern extending to a fourth depth deeper than the third depth inside the first element isolation pattern, and a third gate structure placed on the third active region, in which the first element isolation pattern and the second element isolation pattern include different materials from each other.

In some implementations, a semiconductor memory device includes a cell region; and a peripheral circuit region electrically connected to the cell region, in which the cell region includes a plurality of gate electrodes which are spaced apart from each other and stacked in a vertical direction, and a channel structure which penetrates the plurality of gate electrodes in the vertical direction, in which the peripheral circuit region includes a substrate including first and second sides opposite to each other, a first element isolation structure which defines a first active region in the substrate and is formed inside a first trench having a first width, a first gate structure which extends in a direction intersecting the first active region, and is placed on the first active region, a second element isolation structure which defines a second active region in the substrate, and is formed in a second trench having a second width smaller than the first width, a second gate structure which extends in a direction intersecting the second active region, and is placed on the second active region, a third element isolation structure which defines a third active region in the substrate, and is formed in a third trench having a third width and a fourth trench having a fourth width smaller than the third width, and a third gate structure which extends in a direction intersecting the third active region and is placed on the third active region, in which a bottom side of the fourth trench is closer to the first side of the substrate than a bottom side of the second trench.

In some implementations, a semiconductor memory device includes a cell structure; and a peripheral circuit structure electrically connected to the cell structure, in which the cell structure includes a plurality of gate electrodes which are spaced apart from each other and stacked in a vertical direction, a channel structure which penetrates the plurality of gate electrodes in the vertical direction; and a bit line connected to the channel structure, in which the peripheral circuit structure includes a substrate including first and second regions in which different first and second peripheral circuit elements are each formed, a first element isolation structure which is formed in the first region of the substrate and extends to a first depth, a second element isolation structure which is formed in the second region of the substrate and extends to a second depth deeper than the first depth, and a third element isolation structure which is formed in at least one of the first region and the second region of the substrate, and includes a first element isolation pattern extending to a third depth, and a second element isolation pattern extending to a fourth depth deeper than the third depth inside the first element isolation pattern, in which a first width of the first element isolation structure is greater than a second width of the second element isolation structure, a third width of the first element isolation pattern is greater than a fourth width of the second element isolation pattern, the second width of the second element isolation structure is the same as the fourth width of the second element isolation pattern, and the first element isolation pattern and the second element isolation pattern include different materials from each other.

Specific details of other implementations are included in the description and drawings.

### BRIEF DESCRIPTION OF THE DRAWINGS

The above and other aspects and features of the present disclosure will become more apparent by describing in detail example implementations thereof with reference to the attached drawings.

FIG. 1 is an example block diagram for explaining a semiconductor memory device.

FIG. 2 is an example circuit diagram for explaining a semiconductor memory device.

FIG. 3 is an example cross-sectional view of the semiconductor memory device.

FIG. 4 is an example enlarged view of a region R of FIG. 3.

FIG. 5 is an example plan view for explaining a peripheral circuit structure of the semiconductor memory device.

FIG. 6 is an example cross-sectional view taken along a line A-A of FIG. 5.

FIG. 7 is an example cross-sectional view taken along a line B-B of FIG. 5.

FIG. 8 is an example cross-sectional view taken along a line C-C of FIG. 5.

FIGS. 9 and 10 are example cross-sectional views taken along the line B-B and line C-C of FIG. 5, respectively.

FIG. 11 is an example cross-sectional view taken along line C-C of FIG. 5.

FIG. 12 is an example cross-sectional view taken along line C-C of FIG. 5.

FIG. 13 is an example cross-sectional view taken along line A-A of FIG. 5.

FIG. 14 is an example cross-sectional view taken along line B-B of FIG. 5.

FIG. 15 is an example cross-sectional view taken along line C-C of FIG. 5.

FIG. 16 is an example cross-sectional view of a semiconductor memory device.

FIGS. 17 to 22 are intermediate stage diagrams for explaining an example method for fabricating a semiconductor memory device.

FIGS. 23 to 24 are intermediate stage diagrams for explaining an example method for fabricating a semiconductor memory device.

FIGS. 25 to 29 are intermediate stage diagrams for explaining an example method for fabricating a semiconductor memory device.

FIGS. 30 to 31 are intermediate stage diagrams for explaining an example method for fabricating a semiconductor memory device.

FIGS. 32 to 33 are intermediate stage diagram for explaining an example method for fabricating a semiconductor memory device.

FIG. 34 is an example block diagram for explaining an electronic system.

FIG. 35 is an example perspective view for explaining an electronic system.

FIG. 36 is an example schematic cross-sectional view taken along line I-I of FIG. 35.

### DETAILED DESCRIPTION

Although terms such as first and second are used to describe various elements or components in the present specification, these elements or components are not limited by these terms. These terms are only used to distinguish a single element or component from other elements or components. Therefore, a first element or component referred to below may be a second element or component within the technical idea of the present disclosure.

Hereinafter, in order to describe the present disclosure, some implementations of the present disclosure will be explained in more detail with reference to the accompanying drawings.

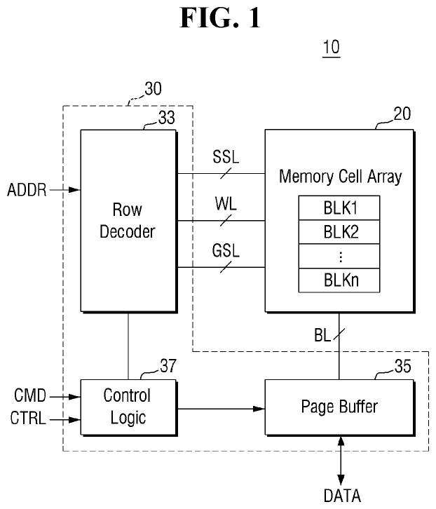

FIG. 1 is an example block diagram for explaining a semiconductor memory device.

Referring to FIG. 1, a semiconductor memory device 10 includes a memory cell array 20 and a peripheral circuit 30.

The memory cell array 20 may include a plurality of memory cell blocks BLK1 to BLKn. Each of the memory cell blocks BLK1 to BLKn may include a plurality of memory cells. The memory cell array 20 may be connected to the peripheral circuit 30 through a bit line BL, a word line WL, at least one string selection line SSL, and at least one ground selection line GSL. Specifically, the memory cell blocks BLK1 to BLKn may be connected to a row decoder 33 through the word line WL, the string selection line SSL, and the ground selection line GSL. Further, the memory cell blocks BLK1 to BLKn may be connected to a page buffer 35 through the bit line BL.

The peripheral circuit 30 may receive an address ADDR, a command CMD, and a control signal CTRL from the outside of the semiconductor memory device 10, and may transmit and receive data DATA to and from an external device of the semiconductor memory device 10. The peripheral circuit 30 may include a control logic 37, a row decoder 33, and a page buffer 35. Although not shown, the peripheral circuit 30 may further include various sub-circuits, such as an input/output circuit, a voltage generation circuit that generates various voltages necessary for the operation of the semiconductor memory device 10, and an error correction circuit for correcting error of the data DATA that is read from the memory cell array 20.

The control logic 37 may be connected to the row decoder 33, the input/output circuit, and the voltage generation circuit. The control logic 37 may control the overall operation of the semiconductor memory device 10. The control logic 37 may generate various internal control signals used inside the semiconductor memory device 10 in response to the control signal CTRL. For example, the control logic 37 may adjust the voltage levels provided to the word line WL and the bit line BL when performing a memory operation such as a program operation or an erase operation.

The row decoder 33 may select at least one of the plurality of memory cell blocks BLK1 to BLKn in response to the address ADDR, and may select at least one word line WL, at least one string selection line SSL, and at least one ground selection line GSL of the selected memory cell blocks BLK1 to BLKn. Further, the row decoder 33 may send a voltage for performing the memory operation to the word lines WL of the selected memory cell blocks BLK1 to BLKn.

The page buffer 35 may be connected to the memory cell array 20 through the bit line BL. The page buffer 35 may operate as a writer driver or a sense amplifier. Specifically, when performing the program operation, the page buffer 35 may operates as the writer driver, and apply a voltage according to the data DATA to be stored in the memory cell array 20 to the bit line BL. On the other hand, when performing the read operation, the page buffer 35 may operate as a sense amplifier and sense the data DATA stored in the memory cell array 20.

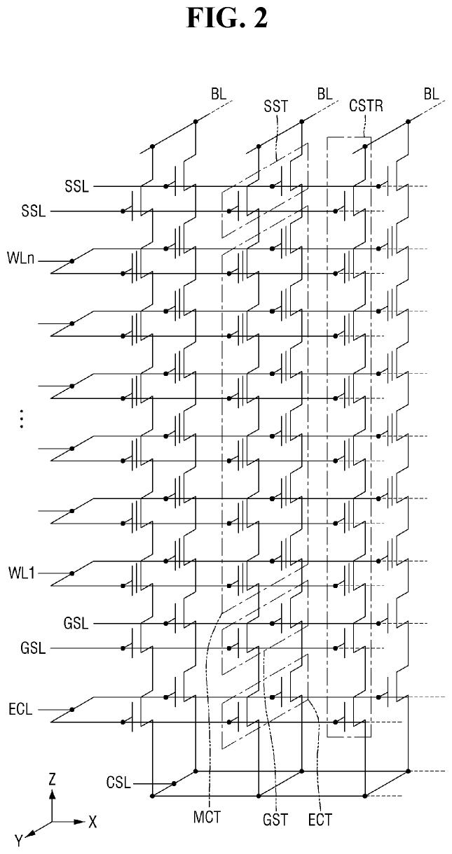

FIG. 2 is an example circuit diagram for explaining a semiconductor memory device.

Referring to FIG. 2, the memory cell array (e.g., 20 of FIG. 1) of the semiconductor device may include a common source line CSL, a plurality of bit lines BL, and a plurality of cell strings CSTR.

The common source line CSL may extend in a first direction X. In some implementations, a plurality of common source lines CSL may be arranged two-dimensionally. For example, the plurality of common source lines CSL may be spaced apart from each other and each extend in the first direction X. The same voltage may be electrically applied to the common source lines CSL, or different voltages are applied to the common source lines CSL and the common source lines CSL may be controlled separately.

The plurality of bit lines BL may be arranged two-dimensionally. For example, the bit lines BL are spaced apart from each other, and may each extend in a second direction Y that intersects the first direction X. A plurality of cell strings CSTR may be connected in parallel to each bit line BL. The cell strings CSTR may be commonly connected to the common source line CSL. That is, the plurality of cell strings CSTR may be placed between the bit lines BL and the common source line CSL.

Each cell string CSTR may include a ground selection transistor GST connected to the common source line CSL, a string selection transistor SST connected to the bit line BL, and a plurality of memory cell transistors MCT placed between the ground selection transistor GST and the string selection transistor SST. Each memory cell transistor MCT may include a data storage element. The ground selection transistor GST, the string selection transistor SST and the memory cell transistors MCT may be connected in series in the third direction Z. In some implementations, the first direction X, the second direction Y, and the third direction Z may be substantially perpendicular to each other.

The common source line CSL may be commonly connected to sources of the ground selection transistors GST. Also, the ground selection line GSL, a plurality of word lines WL1 to WLn, and the string selection line SSL may be placed between the common source line CSL and the bit line BL. The ground selection line GSL may be used as a gate electrode of the ground selection transistor GST, the word lines WL1 to WLn may be used as gate electrodes of the memory cell transistors MCT, and the string selection line SSL may be used as the gate electrode of the string selection transistor SST.

In some implementations, an erasure control transistor ECT may be placed between the common source line CSL and the ground selection transistor GST. The common source line CSL may be commonly connected to the sources of the erasure control transistors ECT. Further, an erasure control line ECL may be placed between the common source line CSL and the ground selection line GSL. The erasure control line ECL may be used as the gate electrode of the erasure control transistor ECT. The erasure control transistors ECT may generate a gate induced drain leakage (GIDL) to perform the erasure operation of the memory cell array.

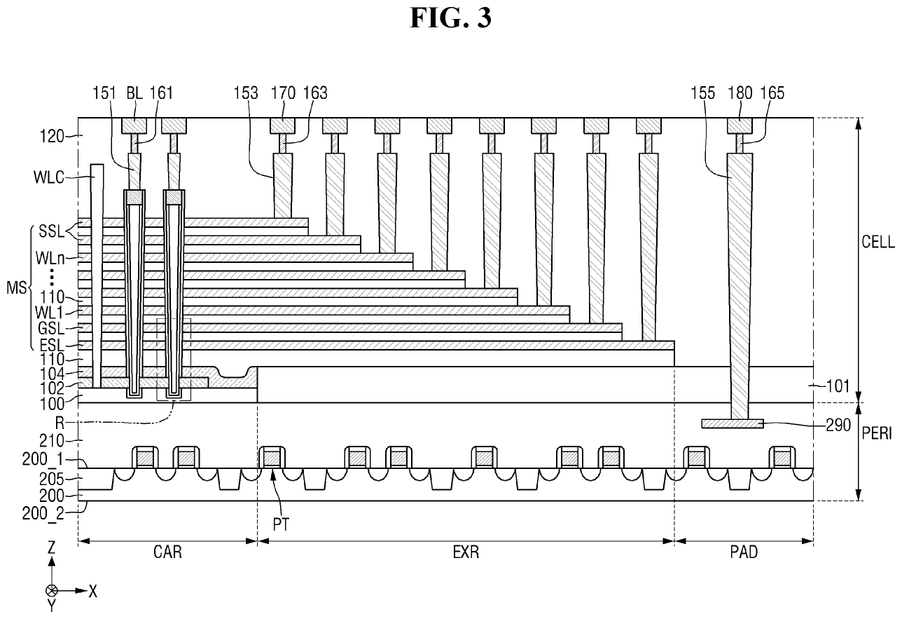

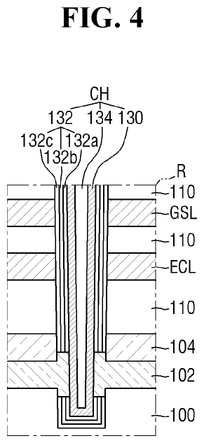

FIG. 3 is an example cross-sectional view of a semiconductor memory device. FIG. 4 is an example enlarged view of a region R of FIG. 3.

Referring to FIGS. 3 and 4, a semiconductor memory device includes a cell structure CELL and a peripheral circuit structure PERI.

In some implementations, the cell structure CELL includes a cell substrate 100, a mold structure MS, a cell interlayer insulating film 120, a channel structure CH, a word line cutting structure WLC, a bit line BL, a plurality of cell contacts 153, and a through contact 155.

The semiconductor memory device may include a cell array region CAR, an extended region EXR, and a pad region PAD. Although the cell array region CAR, the extended region EXR, and the pad region PAD are shown as being connected to each other, the technical idea of the present disclosure is not limited thereto.

A memory cell array (e.g., 20 of FIG. 1) including a plurality of memory cells may be formed in the cell array region CAR. For example, a channel structure CH, a bit line BL, gate electrodes ECL, GSL, WL1 to WLn and SSL, and the like, which will be explained below, may be placed in the cell array region CAR.

The extended region EXR may be placed around the cell array region CAR. The gate electrodes ECL, GSL, WL1 to WLn and SSL, which will be explained below, may be stacked in the extended region EXR in a stepwise manner. Furthermore, a plurality of cell contacts 153 which will be explained below and the like may be placed in the extended region EXR.

The pad region PAD may be placed inside the cell array region CAR and the extended region EXR, or may be placed outside the cell array region CAR and the extended region EXR. The through contact 155 which will be explained below or the like may be placed in the pad region PAD.

The substrate may include the cell array region CAR, the extended region EXR, and the pad region PAD. The substrate may include, but is not limited to, a cell substrate 100 and an insulating pattern 101.

The cell substrate 100 may include, for example, a semiconductor substrate such as a silicon substrate, a germanium substrate or a silicon-germanium substrate. Alternatively, the cell substrate 100 may include a silicon-on-insulator (SOI) substrate, a germanium-on-insulator (GOI) substrate, and the like. In some implementations, the cell substrate 100 may include impurities. For example, the cell substrate 100 may include n-type impurities (e.g., phosphorus (P), arsenic (As), etc.).

The insulating pattern 101 may be provided in the extended region EXR and the pad region PAD. The insulating pattern 101 may include, for example, but is not limited to, at least one of silicon oxide, silicon nitride, silicon oxynitride, and silicon carbide. Unlike the shown example, the insulating pattern 101 may be provided in the cell substrate 100.

The mold structure MS may be provided on a front side (for example, an upper side) of the cell substrate 100. The mold structure MS may include a plurality of gate electrodes ECL, GSL, WL1 to WLn and SSL, and a plurality of mold insulating films 110, which are alternately stacked on the cell substrate 100. Each of the gate electrodes ECL, GSL, WL1 to WLn and SSL and each mold insulating film 110 may have a layered structure extending to be parallel to the upper side of the cell substrate 100. The gate electrodes ECL, GSL, WL1 to WLn, and SSL may be spaced apart from each other by the mold insulating film 110, and may be sequentially stacked on the cell substrate 100.

The gate electrodes ECL, GSL, WL1 to WLn, and SSL may be stacked in the extended region EXR in a stepwise manner. For example, the gate electrodes ECL, GSL, WL1 to WLn, and SSL may extend at different lengths in the first direction X and have steps. In some implementations, the gate electrodes ECL, GSL, WL1 to WLn and SSL may have steps in the second direction Y. Accordingly, each of the gate electrodes ECL, GSL, WL1 to WLn, and SSL may be exposed from other gate electrodes. The exposed region may refer to a region in which each of the plurality of cell contacts 153 and the gate electrodes are in contact with each other.

In some implementations, the gate electrodes ECL, GSL, WL1 to WLn, and SSL include an erasure control line ECL, a ground selection line GSL, and a plurality of word lines WL1 to WLn, which are sequentially stacked on the cell substrate 100. In some implementations, the erasure control line ECL may be omitted.

The mold insulating films 110 may be stacked in the extended region EXR in a stepwise manner. For example, the mold insulating films 110 may extend at different lengths in the first direction X and have steps. In some implementations, the mold insulating films 110 may have steps in the second direction Y.

The gate electrodes ECL, GSL, WL1 to WLn, and SSL may each include a conductive material, for example, but are not limited to, a metal such as tungsten (W), cobalt (Co) and nickel (Ni), or the same semiconductor material as silicon. As an example, each of the gate electrodes ECL, GSL, WL1 to WLn, and SSL may include tungsten (W). Unlike the shown example, the gate electrodes ECL, GSL, WL1 to WLn, and SSL may be multiple films. For example, when the gate electrodes ECL, GSL, WL1 to WLn and SSL are multiple films, the gate electrodes ECL, GSL, WL1 to WLn and SSL may include a gate electrode barrier film and a gate electrode filling film. The gate electrode barrier film may include, for example, titanium nitride (TiN), and the gate electrode filling film may include tungsten (W), but the implementation is not limited thereto.

The mold insulating film 110 may include, but is not limited to, an insulating material, for example, at least one of silicon oxide, silicon nitride and silicon oxynitride. As an example, the mold insulating film 110 may include silicon oxide.

The channel structure CH may be formed inside the mold structure MS of the cell array region CAR. The channel structure CH may extend in a vertical direction (the third direction Z) intersecting the upper side of the cell substrate 100 and penetrate the mold structure MS and the gate electrodes ECL, GSL, WL1 to WLn and SSL. For example, the channel structure CH may have a pillar shape (e.g., a columnar shape) extending in the third direction Z. Therefore, the channel structure CH may intersect each of the gate electrodes ECL, GSL, WL1 to WLn and SSL.

The channel structure CH may include a semiconductor pattern 130 and an information storage film 132.

The semiconductor pattern 130 may extend in the third direction Z and penetrate the mold structure MS. The semiconductor pattern 130 is only shown to have a cup shape, this is merely an example. For example, the semiconductor pattern 130 may have various shapes such as a cylindrical shape, a rectangular barrel shape, and a solid filler shape. The semiconductor pattern 130 may include, but is not limited to, a semiconductor material such as, for example, single crystal silicon, polycrystalline silicon, organic semiconductor substance and carbon nanostructure.

The information storage film 132 may be interposed between the semiconductor pattern 130 and each of the gate electrodes ECL, GSL, WL1 to WLn and SSL. For example, the information storage film 132 may extend along the outer side face of the semiconductor pattern 130. The information storage film 132 may include, for example, at least one of silicon oxide, silicon nitride, silicon oxynitride, and high dielectric constant materials having a higher dielectric constant than silicon oxide. The high dielectric constant material may include, for example, at least one of aluminum oxide, hafnium oxide, lanthanum oxide, tantalum oxide, titanium oxide, lanthanum hafnium oxide, lanthanum aluminum oxide, dysprosium scandium oxide, and combinations thereof.

In some implementations, the information storage film 132 may be formed of a multiple films. For example, as shown in FIG. 4, the information storage film 132 may include a tunnel insulating film 132a, a charge storage film 132b, and a blocking insulating film 132c which are sequentially stacked on the outer side face of the semiconductor pattern 130.

The tunnel insulating film 132a may include, for example, silicon oxide or a high dielectric constant material having a higher dielectric constant than silicon oxide (e.g., aluminum oxide (Al₂O₃), and hafnium oxide (HfO₂)). The charge storage film 132b may include, for example, silicon nitride. The blocking insulating film 132c may include, for example, silicon oxide or a high dielectric constant material having a higher dielectric constant than silicon oxide (e.g., aluminum oxide (Al₂O₃), and hafnium oxide (HfO₂)).

In some implementations, the channel structure CH may further include a filling pattern 134. The filling pattern 134 may be formed to fill the inside of the cup-shaped semiconductor pattern 130. The filling pattern 134 may include, but is not limited to, an insulating material, for example, silicon oxide.

In some implementations, the channel structure CH may further include a channel pad 136. The channel pad 136 may be formed to be connected to the semiconductor pattern 130. For example, the channel pad 136 may be formed inside the cell interlayer insulating film 120 to be explained below and connected to the upper part of the semiconductor pattern 130. The channel pad 136 may include, for example, but is not limited to, impurity-doped polysilicon.

In some implementations, a source layer 102 and a source support layer 104 may be sequentially formed on the cell substrate 100. The source layer 102 and the source support layer 104 may be interposed between the cell substrate 100 and the mold structure MS. For example, the source layer 102 and the source support layer 104 may extend along the upper side of cell substrate 100.

In some implementations, the source layer 102 may be formed to be connected to the semiconductor pattern 130 of the channel structure CH. For example, as shown in FIG. 4, the source layer 102 may penetrate the information storage film 132 and come into contact with the semiconductor pattern 130. Such a source layer 102 may be provided as a common source line (e.g., CSL of FIG. 2) of the semiconductor memory device. The source layer 102 may include, for example, but is not limited to, impurity-doped polysilicon or metal.

In some implementations, the channel structure CH may penetrate the source layer 102 and the source support layer 104. For example, a lower part of the channel structure CH may penetrate the source layer 102 and the source support layer 104, and be embedded in the cell substrate 100.

In some implementations, the source support layer 104 may be used as a support layer for preventing the mold stack from collapsing or falling in a replacement process for forming the source layer 102.

Although not shown, a base insulating film may be interposed between the cell substrate 100 and the source layer 102. The base insulating film may include, for example, but is not limited to, at least one of silicon oxide, silicon nitride, and silicon oxynitride.

In some implementations, the insulating pattern 101 may be formed in the extended region EXR and the pad region PAD. Although the upper side of the insulating pattern 101 is only shown as being placed on the same plane as the upper side of the source support layer 104, this is merely an example. As another example, the upper side of the insulating pattern 101 may be higher than the upper side of the source support layer 104.

The word line cutting structure WLC may cut the mold structure MS. The mold structure MS may be cut by the word line cutting structure WLC to form a plurality of memory cell blocks (e.g., BLK1 to BLKn of FIG. 1). For example, although not shown, two adjacent word line cut structures WLC may define a single memory cell block between them. A plurality of channel structures CH may be placed in each memory cell block defined by the word line cut structures WLC.

In some implementations, the word line cutting structure WLC may cut the source layer 102 and the source support layer 104. Although the lower side of the word line cutting structure WLC is only shown as being placed on the same plane as the lower side of the source layer 102, this is only an example. As another example, the lower side of the word line cutting structure WLC may be lower than the lower side of the source layer 102.

In some implementations, the word line cut structure WLC may include an insulating material. For example, an insulating material may fill the word line cut structure WLC. The insulating material may include, for example, but is not limited to, at least one of silicon oxide, silicon nitride, and silicon oxynitride.

Although not shown, a string isolation structure may be provided in the mold structure MS. The string isolation structure may cut the string selection line SSL. Each memory cell block defined by the word line cut structures WLC may be divided by the string isolation structure to form a plurality of string regions. For example, the string isolation structure may define two string regions inside the single memory cell block.

A cell interlayer insulating film 120 may be placed on the mold structure MS. The cell interlayer insulating film 120 may cover the plurality of channel structures CH, the plurality of cell contacts 153, and the through contacts 155. The cell interlayer insulating film 120 may include an oxide-based insulating material. The cell interlayer insulating film 120 may include, for example, but is not limited to, at least one of silicon oxide, silicon oxynitride, and a low-k material having a dielectric constant lower than that of silicon oxide.

The bit line BL may be placed on the substrate of the cell array region CAR. The bit line BL may be formed on the mold structure MS. The bit line BL may be a bit line (BL of FIG. 2) of a semiconductor memory device. The bit line BL may be placed in the cell interlayer insulating film 120. The bit line BL may extend in the second direction Y.

Further, the bit line BL may be connected to a plurality of channel structures CH. For example, first and second bit line contacts 151 and 161 may be formed in the cell interlayer insulating film 120 connected to the upper part of each channel structure CH. A first bit line contact 151 is placed on the channel structure CH. The first bit line contact 151 may be connected to the channel pad 136. A second bit line contact 161 is placed on the first bit line contact 151. The second bit line contact 161 may be connected to the bit line BL. The second bit line contact 161 may be provided between each bit line BL and the first bit line contact 151. The bit line BL may be electrically connected to the channel structure CH through the first and second bit line contacts 151 and 161.

The bit line BL may include a conductive material. For example, the bit line BL may include, but is not limited to, tungsten (W) or copper (Cu).

A plurality of cell contacts 153 may be provided on the substrate of the extended region EXR. The plurality of cell contacts 153 may extend in the third direction Z in the extended region EXR, and penetrate the cell interlayer insulating film 120. Each of the plurality of cell contacts 153 may be connected to one of the plurality of gate electrodes ECL, GSL, WL1 to WLn, and SSL. For example, each of the plurality of cell contacts 153 may be landed on a gate electrode placed at the highest level among the plurality of gate electrodes ECL, GSL, WL1 to WLn, and SSL. That is, each of the plurality of cell contacts 153 may be electrically connected to the gate electrode placed at the highest level among the plurality of gate electrodes ECL, GSL, WL1 to WLn, and SSL.

The upper sides of each of the plurality of cell contacts 153 may all be placed on the same plane. Furthermore, the bottom sides of each of the plurality of cell contacts 153 may be placed on the same plane. However, the technical idea of the present disclosure is not limited thereto.

A plurality of first metal patterns 170 may be placed on the substrate of the extended region EXR. The plurality of first metal patterns 170 may be placed on the mold structure MS. The plurality of first metal patterns 170 may be connected to each of the plurality of cell contacts 153. For example, a first via contact 163 may be formed between the plurality of first metal patterns 170 and each cell contact 153. The plurality of first metal patterns 170 and each cell contact 153 may be electrically connected through the first via contact 163.

The plurality of first metal patterns 170 may include a conductive material. For example, the plurality of first metal patterns 170 may include, but are not limited to, tungsten (W) or copper (Cu).

The through contact 155 may be provided on the substrate of the pad region PAD. The through contact 155 may extend in the third direction Z in the pad region PAD, and penetrate the cell interlayer insulating film 120. Further, the through contact 155 may penetrate the insulating pattern 101. The through contact 155 may penetrate the insulating pattern 101 and be connected to the peripheral circuit element PT of a peripheral circuit structure PERI, which will be explained below. The through contact 155 may be, for example, connected to the wiring pattern 290 of the peripheral circuit structure PERI.

A plurality of second metal patterns 180 may be placed on the substrate of the pad region PAD. The plurality of second metal patterns 180 may be provided in the cell interlayer insulating film 120. The plurality of second metal patterns 180 may be connected to the through contact 155. For example, a second via contact 165 may be formed between the plurality of second metal patterns 180 and the through contact 155. The plurality of second metal patterns 180 and the through contact 155 may be electrically connected through the second via contact 165.

The plurality of second metal patterns 180 may include a conductive material. For example, the plurality of second metal patterns 180 may include, but are not limited to, tungsten (W) or copper (Cu).

In some implementations, the peripheral circuit structure PERI may include a peripheral circuit board 200, an element isolation film 205, and a peripheral circuit element PT.

The peripheral circuit board 200 may be placed under the cell substrate 100. For example, an upper side 200_1 of the peripheral circuit board 200 may be opposite to a lower side of the cell substrate 100. The peripheral circuit board 200 may include the same semiconductor substrate as, for example, a silicon substrate, a germanium substrate or a silicon-germanium substrate. Alternatively, the peripheral circuit board 200 may include a silicon-on-insulator (SOI) substrate, a germanium-on-insulator (GOI) substrate, or the like.

The peripheral circuit element PT may be formed on the peripheral circuit board 200. The peripheral circuit element PT may constitute a peripheral circuit (e.g., 30 of FIG. 1) that controls the operation of the semiconductor memory device. For example, the peripheral circuitry PT may include control logic (e.g., 37 of FIG. 1), a row decoder (e.g., 33 of FIG. 1), a page buffer (e.g., 35 of FIG. 1), and the like. As an example, the peripheral circuit element PT may be a page buffer and may control the operation of the bit line BL, but the technical idea of the present disclosure is not limited thereto.

In the following description, a first side 200_1 of the peripheral circuit board 200 on which the peripheral circuit element PT is placed may be referred to as an upper side of the peripheral circuit board 200. In contrast, a second side 200_2 of the peripheral circuit board 200 opposite to the upper side 200_1 of the peripheral circuit board 200 may be referred to as a lower side of the peripheral circuit board 200.

The peripheral circuit element PT may include, for example, but is not limited to, a transistor. For example, the peripheral circuit element PT may include not only various active elements such as a transistor, but also various passive elements such as a capacitor, a resistor, and an inductor.

In some implementations, the back side of the cell substrate 100 may be opposite to the upper side 200_1 of the peripheral circuit board 200. For example, a peripheral circuit interlayer insulating film 210 that covers the peripheral circuit element PT may be formed on the upper side 200_1 of the peripheral circuit board 200. The cell substrate 100 and/or the insulating pattern 101 may be stacked on the upper side of the peripheral circuit interlayer insulating film 210.

The plurality of second metal patterns 180 may be connected to the peripheral circuit element PT through the through contact 155. For example, a wiring pattern 290 connected to the peripheral circuit element PT may be formed in the peripheral circuit interlayer insulating film 210. The bit line BL, each of the gate electrodes ECL, GSL, WL1 to WLn and SSL, and/or the source layer 102 may be electrically connected to the peripheral circuit element PT through the wiring pattern 290.

The peripheral circuit elements PT may be separated by the element isolation film 205. For example, the element isolation film 205 may be provided in the peripheral circuit board 200. The element isolation film 205 may be a shallow isolation (STI) film and/or a deep trench isolation film. The element isolation film 205 may define an active region of the peripheral circuit elements PT. The element isolation film 205 may include an insulating material. The element isolation film 205 may include, for example, at least one of silicon nitride, silicon oxide, and silicon oxynitride.

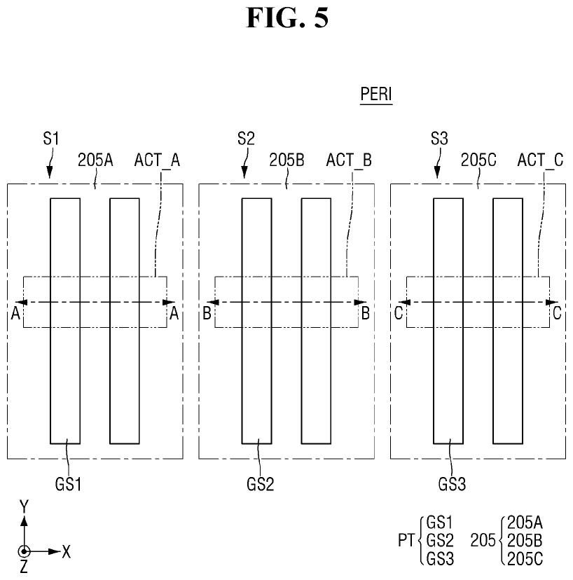

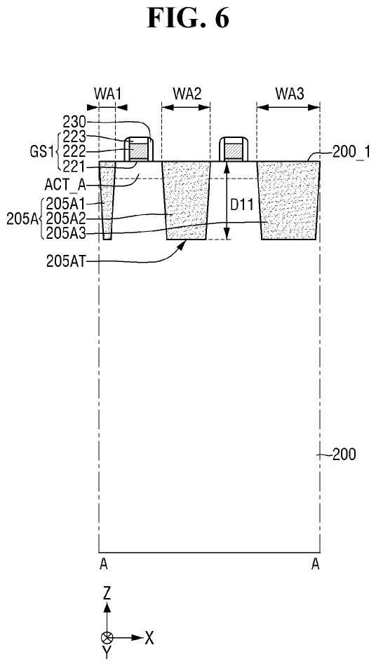

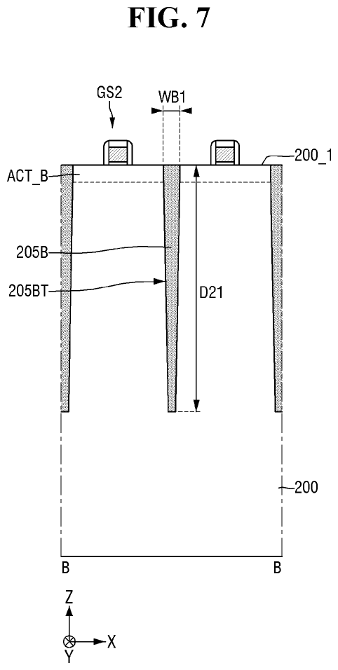

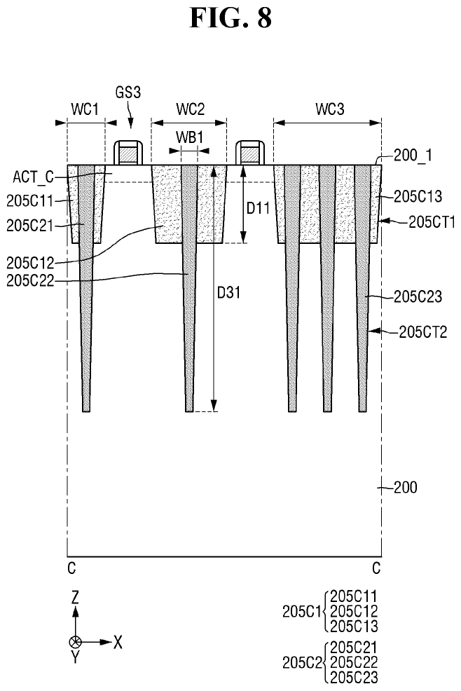

The peripheral circuit element PT will be explained in more detail using FIGS. 5 to 8. FIG. 5 is an example plan view for explaining a peripheral circuit structure of a semiconductor memory device. FIG. 6 is an example cross-sectional view taken along line A-A of FIG. 5. FIG. 7 is an example cross-sectional view taken along line B-B of FIG. 5. FIG. 8 is an example cross-sectional view taken along line C-C of FIG. 5.

Referring to FIGS. 5 to 8, the semiconductor memory device may include a peripheral circuit board 200, a first active region ACT_A, a first element isolation structure 205A, a first gate structure GS1, a second active region ACT_B, a second element isolation structure 205B, a second gate structure GS2, a third active region ACT_C, a third element isolation structure 205C, and a third gate structure GS3. Each of the first to third gate structures GS1, GS2, and GS3 may be included in the first to third transistors included in the peripheral circuit element PT.

The peripheral circuit board 200 may include first to third regions S1, S2, and S3. Each of the first to third regions S1, S2, and S3 may mean regions in which each of the first to third element isolation structures 205A, 205B, and 205C is formed. The first to third regions S1, S2, and S3 may mean regions corresponding to at least one of the cell array region CAR, the extended region EXR, and the pad region PAD.

In some implementations, the first element isolation structure 205A may be formed in a region corresponding to at least one of the cell array region CAR, the extended region EXR, and the pad region PAD. The second element isolation structure 205B may be formed in a region corresponding to at least one of the extended region EXR and the pad region PAD. The third element isolation structure 205C may be formed in a region corresponding to at least one of the cell array region CAR, the extended region EXR, and the pad region PAD.

The first active region ACT_A may be placed on the peripheral circuit board 200. The first active region ACT_A may be used as a channel of a first transistor including the first gate structure GS1. The first gate structure GS1 may be placed on the first active region ACT_A. The first active region ACT_A may extend in the first direction X. The first direction X and the second direction Y may be directions that are parallel to the upper side 200_1 of the peripheral circuit board 200 and intersect each other. The third direction Z may intersect each of the first direction X and the second direction Y. The third direction Z may be a direction perpendicular to the upper side of the peripheral circuit board 200. That is, the third direction Z may be a vertical direction.

The first gate structure GS1 may extend in the second direction Y on the first active region ACT_A. The first gate structure GS1 may extend to intersect the first active region ACT_A.

Although the drawings only show that the first active region ACT_A extends in the first direction X and the first gate structure GS1 extends in the second direction Y, the implementation is not limited thereto.

The first gate structure GS1 may include a gate insulating pattern 221, a gate pattern 222, and a gate capping pattern 223. The gate insulating pattern 221, the gate pattern 222, and the gate capping pattern 223 may be sequentially stacked in the third direction Z. The gate insulating pattern 221 is placed on the first active region ACT_A, the gate pattern 222 is placed on the gate insulating pattern 221, and the gate capping pattern 223 may be placed on the gate pattern 222.

The gate insulating pattern 221 may include, for example, silicon oxide, silicon oxynitride, silicon nitride, or a high dielectric constant material having a higher dielectric constant than silicon oxide. Examples of high dielectric constant materials may include one or more of boron nitride, hafnium oxide, hafnium silicon oxide, hafnium aluminum oxide, lanthanum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate. As an example, the gate insulating pattern 221 may be formed of a silicon oxide film.

The gate pattern 222 may include a conductive material. For example, the gate pattern 222 may include, but is not limited to, a polysilicon film doped with impurities, tungsten (W), or a combined film thereof.

The gate capping pattern 223 may be formed of, for example, but is not limited to, a silicon nitride film.

The spacer 230 may cover the first gate structure GS1. The spacer 230 may be placed on the first gate structure GS1. The spacer 230 may cover the upper side and side walls of the first gate structure GS1. The spacer 230 may include an insulating material. For example, the spacer 230 may be formed of, but is not limited to, a silicon oxide film.

Although it is not specifically shown, a source/drain region may be placed in the first active region ACT_A. The source/drain region may be placed on at least one side of the first gate structure GS1. The source/drain regions may be placed on both sides of the first gate structure GS1. The source/drain region may be a region doped with impurities. For example, if the first gate structure GS1 is a PMOS transistor, the source/drain regions may be doped with p-type impurities. As another example, when the first gate structure GS1 is an NMOS transistor, the source/drain regions may be doped with n-type impurities.

The second active region ACT_B may be placed on the peripheral circuit board 200. The second active region ACT_B may be used as a channel of a second transistor including the second gate structure GS2. The second gate structure GS2 may be placed on the second active region ACT_B. The second active region ACT_B may extend in the first direction X.

The second gate structure GS2 may extend in the second direction Y on the second active region ACT_B. The second gate structure GS2 may extend to intersect the second active region ACT_B.

The third active region ACT_C may be placed on the peripheral circuit board 200. The third active region ACT_C may be used as a channel of a third transistor including the third gate structure GS3. The third gate structure GS3 may be placed on the third active region ACT_C. The third active region ACT_C may extend in the first direction X.

The third gate structure GS3 may extend in the second direction Y on the third active region ACT_C. The third gate structure GS3 may extend to intersect the third active region ACT_C.

The description of the first active region ACT_A and first gate structure GS1 may also be similarly applicable to the second active region ACT_B, the second gate structure GS2, the third active region ACT_C, and the third gate structure GS3.

Referring to FIG. 6, the first element isolation structure 205A may be formed in the first trench 205AT of the first width (any one of WA1, WA2, and WA3) on the basis of the first direction X.

A plurality of first element isolation structures 205A with different widths from each other may be formed. The first element isolation structure 205A may include first to third element isolation patterns 205A1, 205A2, and 205A3 having different widths (any one of WA1, WA2, and WA3) from each other.

For example, the first element isolation structure 205A and the first trench 205AT may have a width of 2000 nm or less, but are not limited thereto.

The first trench 205AT and the first element isolation structure 205A may extend to a first depth D11 on the basis of the third direction Z. For example, the first depth D11 may be equal to or less than 4000 Å. More specifically, the first depth D11 may be, but is not limited to, equal to or less than 3000 Å to 4000 Å.

Referring to FIG. 7, the second element isolation structure 205B may be formed in a second trench 205BT of a second width WB1 on the basis of the first direction X. The second width WB1 may be smaller than the first width (any one of WA1, WA2, and WA3).

The second element isolation structure 205B may have the second width WB1 on the basis of the first direction X. The first width (any one of WA1, WA2, and WA3) of the first element isolation structure 205A may be, but is not limited to, greater than the second width WB1 of the second element isolation structure 205B. For example, the second element isolation structure 205B and the second trench 205BT may have a width of 150 nm or less.

The second trench 205BT and the second element isolation structure 205B may extend to a second depth D21 on the basis of the third direction Z. The second depth D21 may be deeper than the first depth D11. For example, the second depth D21 may be equal to or less than 15,000 Å. More specifically, the second depth D21 may be, but is not limited to, equal to or less than 10,000 Å to 15,000 Å.

Referring to FIG. 8, the third element isolation structure 205C may be formed in the third trench 205CT1 of third width (any one of WC1, WC2, and WC3) and a fourth trench 205CT2 of a fourth width WB1 on the basis of the first direction X. The fourth width WB1 may be smaller than any one of the third widths WC1, WC2, and WC3.

The third element isolation structure 205C may include a first element isolation pattern 205C1 formed in the third trench 205CT1, and a second element isolation pattern 205C2 formed in the fourth trench 205CT2. The second element isolation pattern 205C2 may be formed in the first element isolation pattern 205C1. The third element isolation structure 205C has a funnel shape in which the second element isolation pattern 205C2 having a narrow width and a deep depth is formed inside the first element isolation pattern 205C1 having a relatively wide width and a shallow depth.

The first element isolation pattern 205C1 may have a third width WC1, WC2, or WC3 on the basis of the first direction X. The second element isolation pattern 205C2 may have a fourth width WB1 on the basis of the first direction X. The fourth width WB1 of the second element isolation pattern 205C2 may be the same as the second width WB1 of the second element isolation structure 205B. The third width (any one of WC1, WC2, and WC3) of the first element isolation pattern 205C1 may be greater than the fourth width WB1 of the second element isolation pattern 205C2.

For example, each of the first element isolation pattern 205C1 and the third trench 205CT1 may have a width of 2000 nm or less. For example, each of the widths WB1 of the second element isolation pattern 205C2 and the fourth trench 205CT2 may be 150 nm or less.

A plurality of first element isolation patterns 205C1 with different widths from each other may be formed. The first element isolation pattern 205C1 may include first to third element isolation patterns 205C11, 205C12, and 205C13 having different widths WC1, WC2, and WC3 from each other.

A plurality of second element isolation patterns 205C2 with the same widths as each other may be formed. The second element isolation pattern 205C2 may include first to third element isolation patterns 205C21, 205C22, and 205C23 having the same width WB1 as each other.

The third trench 205CT1 and the first element isolation pattern 205C1 may extend at a third depth D11 on the basis of the third direction Z. The fourth trench 205CT2 and the second element isolation pattern 205C2 may extend at a fourth depth D31 on the basis of the third direction Z.

The first depth D11 of the third trench 205CT1 and the first element isolation structure 205A may be the same as the third depth D11 of the first trench 205AT and the first element isolation pattern 205C1. The fourth depth D31 of the fourth trench 205CT2 and the second element isolation pattern 205C2 may be the same as the second depth D21 of the second trench 205BT and the second element isolation structure 205B.

In this case, on the basis of the third direction Z, the bottom side of the first trench 205AT is placed on the same plane as the bottom side of the third trench 205CT1, and the bottom side of the second trench 205BT may be placed on the same plane as the bottom side of the fourth trench 205CT2. The upper side of the first element isolation pattern 205C1 and the upper side of the second element isolation pattern 205C2 may be placed on the same plane as the upper side 200_1 of the peripheral circuit board 200.

However, in some implementations to be explained below, the fourth depth D31 of the second element isolation pattern 205C2 may be different from the second depth D21 of the second element isolation structure 205B.

On the basis of the third direction Z, the bottom side of the first trench 205AT may be closer to the upper side 200_1 of the peripheral circuit board 200 than the bottom side of the second trench 205BT. The bottom side of the third trench 205CT1 may be closer to the upper side 200_1 of the peripheral circuit board 200 than the bottom side of the fourth trench 205CT2.

The first element isolation structure 205A and the second element isolation structure 205B may include different materials from each other. For example, the first element isolation structure 205A and the second element isolation structure 205B may include materials having different physical properties from each other. For example, the first element isolation structure 205A and the second element isolation structure 205B may include different impurities from each other.

The first element isolation pattern 205C1 and the second element isolation pattern 205C2 may include different materials from each other. For example, the first element isolation pattern 205C1 and the second element isolation pattern 205C2 may include materials having different physical properties from each other. For example, the first element isolation pattern 205C1 and the second element isolation pattern 205C2 may include different impurities from each other.

The materials included in the first element isolation structure 205A and the first element isolation pattern 205C1 may be the same. The materials included in the second element isolation structure 205B and the second element isolation pattern 205C2 may be the same.

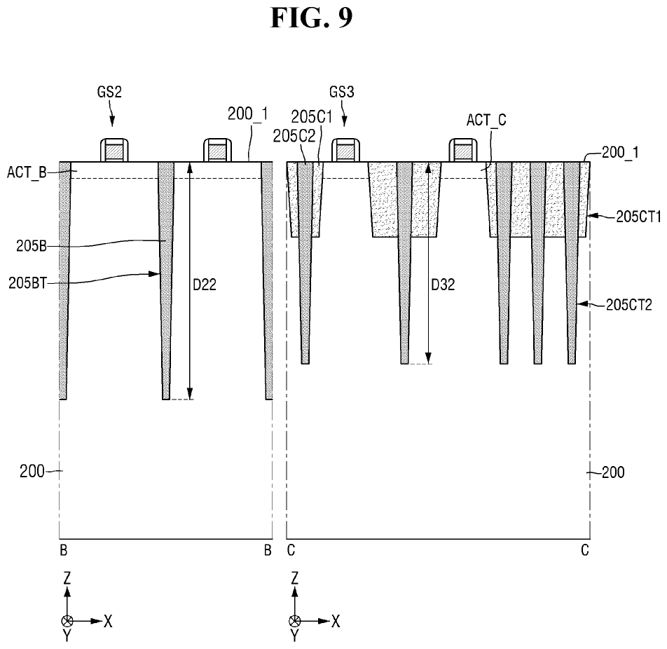

Hereinafter, a semiconductor memory device according to some implementations of the present disclosure will be explained with reference to FIGS. 9 to 14.

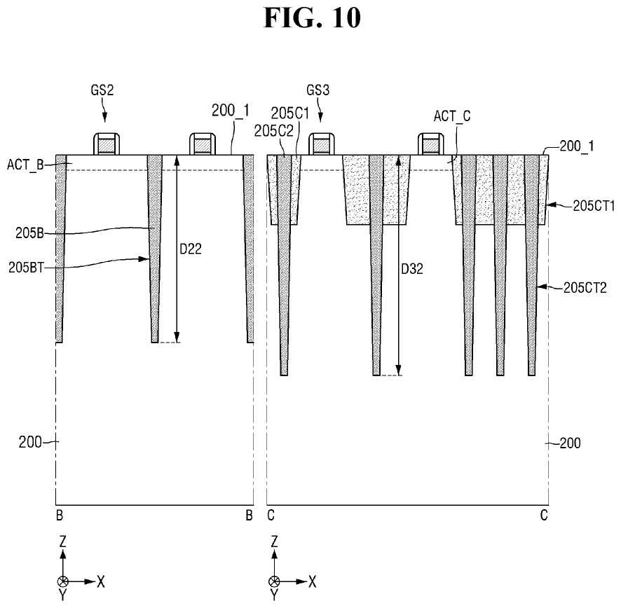

FIGS. 9 and 10 are example cross-sectional views taken along the line B-B and line C-C of FIG. 5, respectively. For convenience of explanation, repeated contents of those explained using FIGS. 1 to 8 will be briefly explained or omitted.

Referring to FIG. 9, in the semiconductor memory device, a fourth depth D32 of the second element isolation pattern 205C2 may be smaller than the second depth D22 of the second element isolation structure 205B. That is, the fourth depth D32 of the fourth trench 205CT2 may be smaller than the second depth D22 of the second trench 205BT. In this case, the bottom side of the fourth trench 205CT2 may be placed to be closer to the upper side 200_1 of the peripheral circuit board 200 than the bottom side of the second trench 205BT, on the basis of the third direction Z.

Referring to FIG. 10, in the semiconductor memory device, the fourth depth D32 of the second element isolation pattern 205C2 may be deeper than the second depth D22 of the second element isolation structure 205B. That is, the fourth depth D32 of the fourth trench 205CT2 may be deeper than the second depth D22 of the second trench 205BT. In this case, on the basis of the third direction Z, the bottom side of the second trench 205BT may be placed to be closer to the upper side 200_1 of the peripheral circuit board 200 than the bottom side of the fourth trench 205CT2.

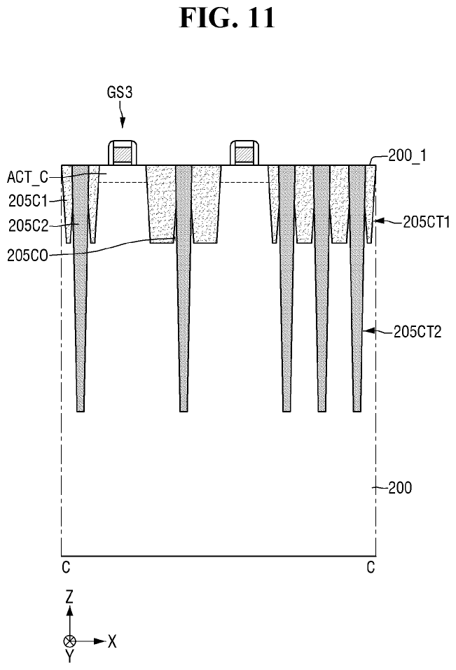

FIG. 11 is an example cross-sectional view taken along line C-C of FIG. 5. For convenience of explanation, repeated contents of those explained using FIGS. 1 to 10 will be briefly explained or omitted.

Referring to FIG. 11, in the semiconductor memory device, the peripheral circuit board 200 may include a fence pattern 205CO formed in at least a part between the first element isolation pattern 205C1 and the second element isolation pattern 205C2. The fence pattern 205CO may have a shape that is recessed toward the upper side 200_1 of the peripheral circuit board 200 between one side wall of the first element isolation pattern 205C1 and one side wall of the second element isolation pattern 205C2.

On the basis of the first direction X, the width of the fence pattern 205CO may become smaller toward the upper side 200_1 of the peripheral circuit board 200. The fence pattern 205CO may include silicon (Si).

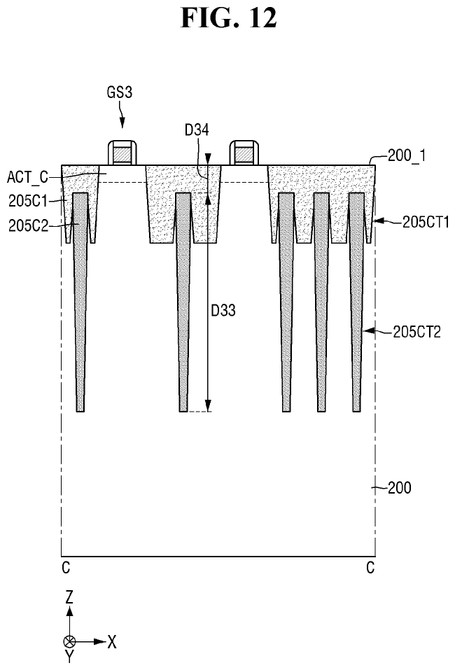

FIG. 12 is an example cross-sectional view taken along line C-C of FIG. 5. For convenience of explanation, repeated contents of those explained using FIGS. 1 to 11 will be briefly explained or omitted.

Referring to FIG. 12, in the semiconductor memory device, the upper side of the first element isolation pattern 205C1 may be placed to be closer to the upper side 200_1 of the peripheral circuit board 200 than the upper side of the second element isolation pattern 205C2.

The upper side 200_1 of the peripheral circuit board 200 and the upper side of the second element isolation pattern 205C2 are placed to be spaced apart by a first distance D34, and the upper side of the second element isolation pattern 205C2 and the bottom side of the fourth trench 205CT2 may be placed to be spaced apart by a second distance D33.

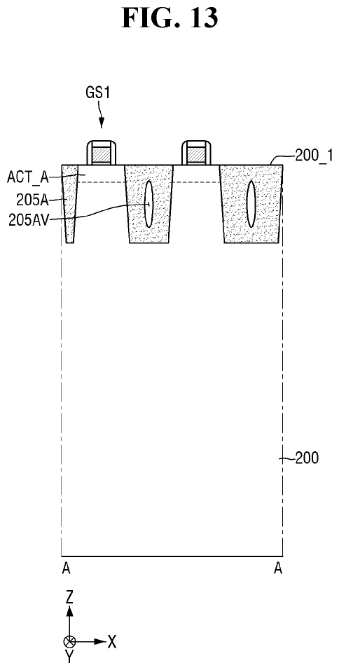

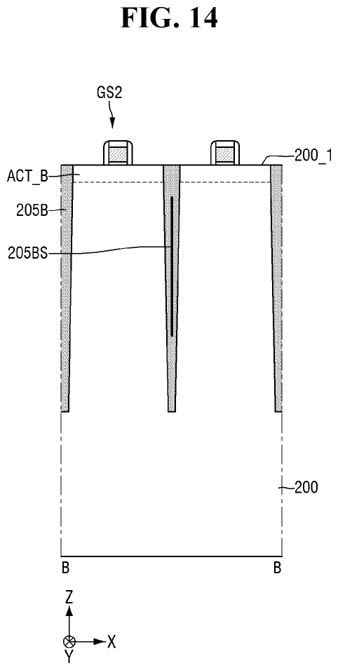

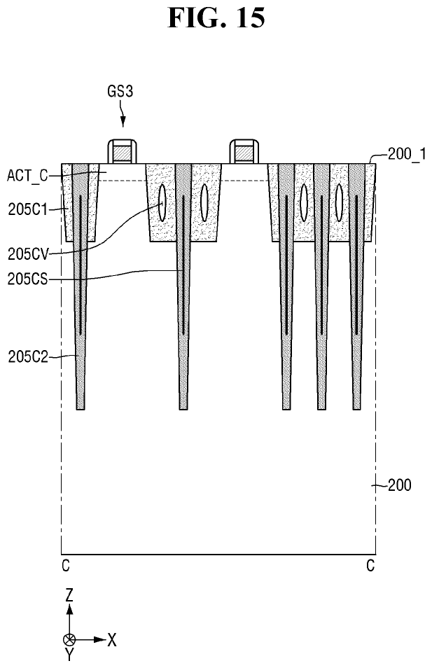

FIG. 13 is an example cross-sectional view taken along line A-A of FIG. 5. FIG. 14 is an example cross-sectional view taken along line B-B of FIG. 5. FIG. 15 is an example cross-sectional view taken along line C-C of FIG. 5. For convenience of explanation, repeated contents of those explained using FIGS. 1 to 12 will be briefly explained or omitted.

Referring to FIGS. 13 to 15, in the semiconductor memory device, a void may be formed in at least a part of the first element isolation structure 205A and the first element isolation pattern 205C1. A void 205AV is formed in at least a part of the first element isolation structure 205A, and a void 205CV may be formed in at least a part of the first element isolation pattern 205C1.

As it will be explained below, this void may have a structure in which the first element isolation structure 205A and the first element isolation pattern 205C1 are formed in a bottom-up manner.

Further, a seam may be formed in at least a part of the second element isolation structure 205B and the second element isolation pattern 205C2. A shim 205BS is formed on at least a part of the second element isolation structure 205B, and a shim 205CS may be formed on at least a part of the second element isolation pattern 205C2.

As it will be explained below, the shim may have a structure in which the second element isolation structure 205B and the second element isolation pattern 205C2 are formed by an atomic layer deposition method.

The shapes, numbers, and positions of the voids and shims are not limited to those shown in the drawings.

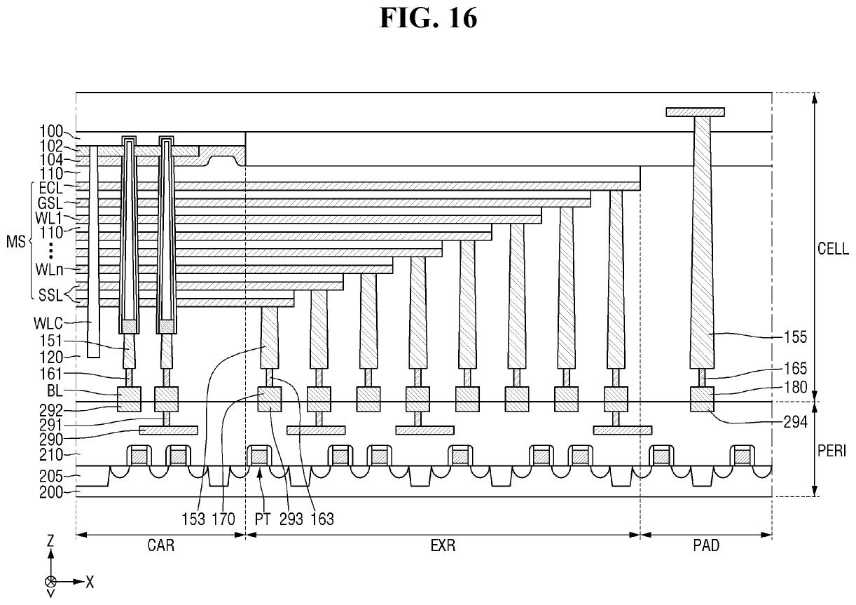

FIG. 16 is an example cross-sectional view of a semiconductor memory device. For convenience of explanation, repeated contents of those explained using FIGS. 1 to 15 will be briefly explained or omitted.

Referring to FIG. 16, in the semiconductor memory device, the front side of the cell substrate 100 faces the upper side of the peripheral circuit board 200.

For example, the semiconductor memory device may have a C2C (chip to chip) structure. The C2C structure may mean a structure in which an upper chip including a cell structure CELL is manufactured on a first wafer (e.g., the cell substrate 100) and a lower chip including the peripheral circuit region PERI is manufactured on a second wafer (e.g., the peripheral circuit board 200) different from the first wafer, and then, the upper chip and the lower chip are connected to each other by a bonding way.

As an example, the bonding way may mean a way of electrically bonding method may include a bit line BL, a plurality of first metal patterns 170 and a second metal pattern 180 formed on the uppermost metal layer of the upper chip to first to third bonding metals 292, 293, and 294 formed on the uppermost metal layer of the lower chip. For example, when the bit line BL, the plurality of first metal patterns 170, the second metal pattern 180, and the first to third bonding metals 292, 293, and 294 are formed of copper (Cu), the bonding way may be a Cu—Cu bonding way. However, this is exemplary only, and each of the bit line BL, the plurality of first metal patterns 170, the second metal pattern 180, and the first to third bonding metals 292, 293, and 294 may, of course, be formed of various other metals such as aluminum (Al) or tungsten (W).

As the bit line BL and the first bonding metal 292 are connected, the plurality of first metal patterns 170 and the second bonding metal 293 are connected, and the second metal pattern 180 and the third bonding metal 294 are connected, the cell structure CELL and the peripheral circuit structure PERI may be electrically connected. For example, the bit line BL and the wiring pattern 290, the plurality of first metal patterns 170 and the wiring pattern 290, and the second metal pattern 180 and the wiring pattern 290 may each be electrically connected to each other through the first to third bonding metals 292, 293 and 294 and the via contact 291. Accordingly, each of the gate electrodes ECL, GSL, WL1 to WLn and SSL and/or the source layer 102 may be electrically connected to the peripheral circuit element PT.

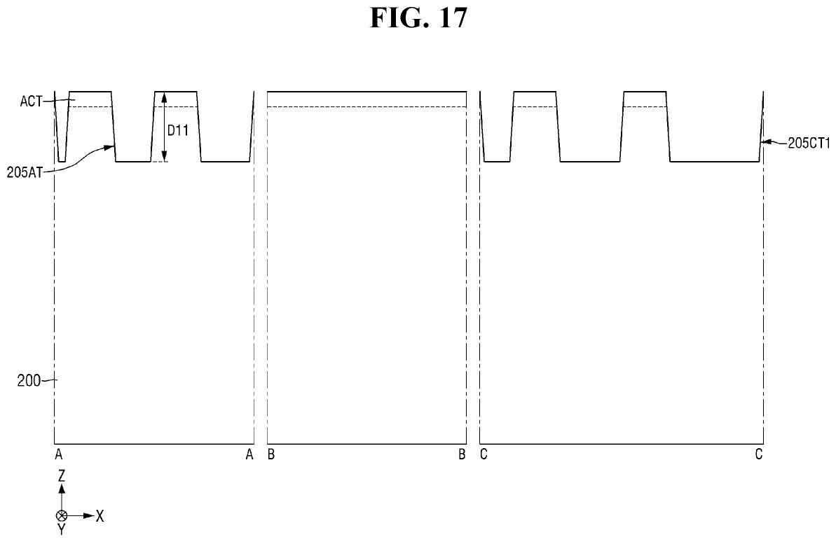

Hereinafter, a method for fabricating a semiconductor memory device according to some implementations of the present disclosure will be explained with reference to FIGS. 17 to 22. FIGS. 17 to 22 are intermediate stage diagrams for explaining an example method for fabricating a semiconductor memory device.

First, referring to FIG. 17, a peripheral circuit board 200 including first to third regions may be provided. Each of the first to third regions may mean a region in which each of the first to third element isolation structures 205A, 205B, and 205C explained above is formed. Each of the first to third regions may mean a region in which each of the first to third transistors explained above is formed.

Although not specifically shown, a mask may be formed on the peripheral circuit board 200. The mask may be formed on the first region and the third region of the peripheral circuit board 200, and may not be formed on the second region. The first trench 205AT and the third trench 205CT1 may be formed in the peripheral circuit board 200 using a mask. Thereafter, the mask may be removed.

The first trench 205AT and the third trench 205CT1 may have a first depth D11 on the basis of the third direction Z. For example, the first depth D11 may be equal to or less than 4000 Å.

A plurality of first trenches 205AT with different widths from each other may be formed on the basis of the first direction X. A plurality of third trenches 205CT1 with different widths from each other may be formed on the basis of the first direction X.

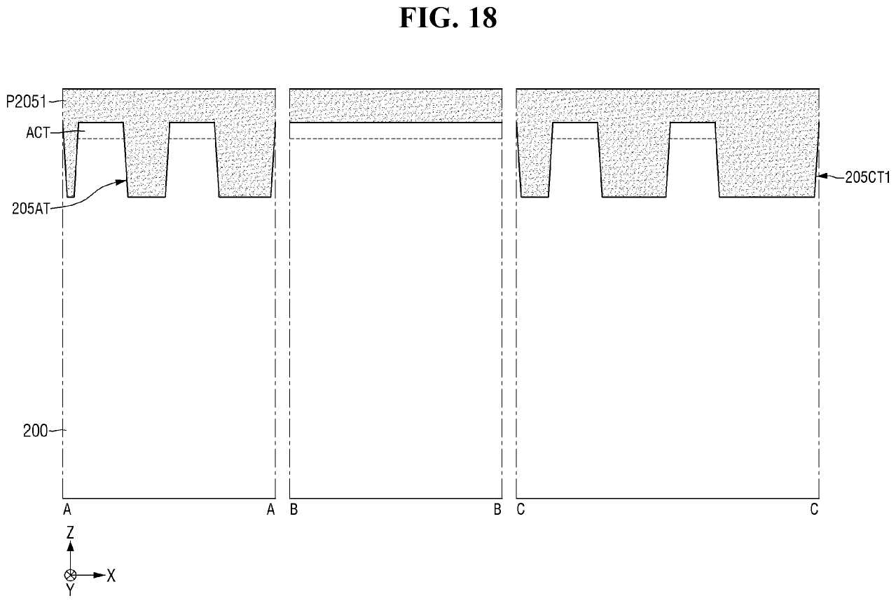

Referring to FIG. 18, a first pre-insulating film P2051 may be formed in the first trench 205AT and the third trench 205CT1 to fill each of the first trench 205AT and the third trench 205CT1. The first pre-insulating film P2051 may include, for example, at least one of silicon nitride, silicon oxide, and silicon oxynitride. The first pre-insulating film P2051 may be formed in a bottom-up manner by, for example, but is not limited to, a chemical vapor deposition (CVD) process.

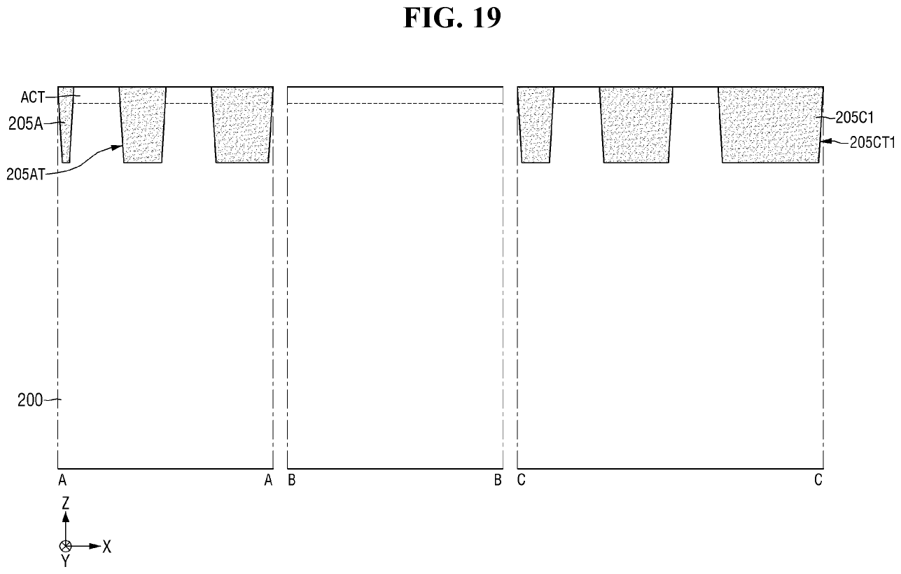

Referring to FIG. 19, by removing at least a part of the first pre-insulating film P2051 of the first to third regions, the first element isolation structure 205A and the first element isolation pattern 205C1 may be formed. In this case, a part of the first pre-insulating film P2051 may be removed so that the upper sides of the first element isolation structure 205A and the first element isolation pattern 205C1 are placed on the same plane, using a chemical mechanical polishing (CMP) process.

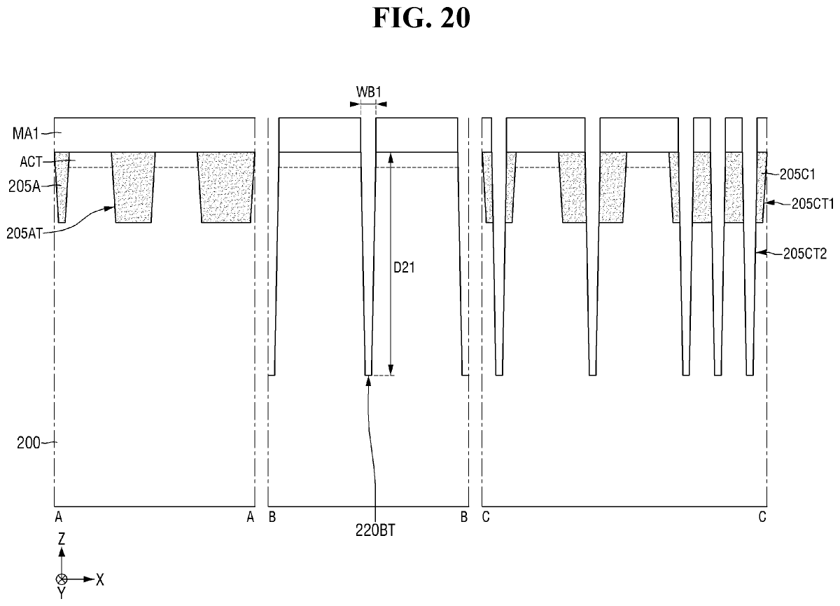

Referring to FIG. 20, a first mask pattern MA1 may be formed in the first to third regions of the peripheral circuit board 200. The first mask pattern MA1 may be formed in the first to third regions except for the region in which the second trench 205BT and the fourth trench 205CT2 are formed. The second trench 205BT and the fourth trench 205CT2 may be formed in the peripheral circuit board 200, using the first mask pattern MA1.

The first mask pattern MA1 may be formed of at least one of a photoresist film, an ACL (Amorphous Carbon Layer), an SOH (Spin on Hardmask), an SOC (Spin on Carbon), and a silicon nitride film.

The fourth trench 205CT2 may be formed to at least partially penetrate the inside of the first element isolation pattern 205C1.

The second trench 205BT and the fourth trench 205CT2 may extend to a second depth D21 on the basis of the third direction Z. For example, the second depth D21 may be equal to or less than 15,000 Å.

On the basis of the first direction X, the widths WB1 of the second trench 205BT and the fourth trench 205CT2 may be equal to each other. For example, each of the widths WB1 of the second trench 205BT and the fourth trench 205CT2 may be 150 nm or less.

Thereafter, the first mask pattern MA1 may be removed.

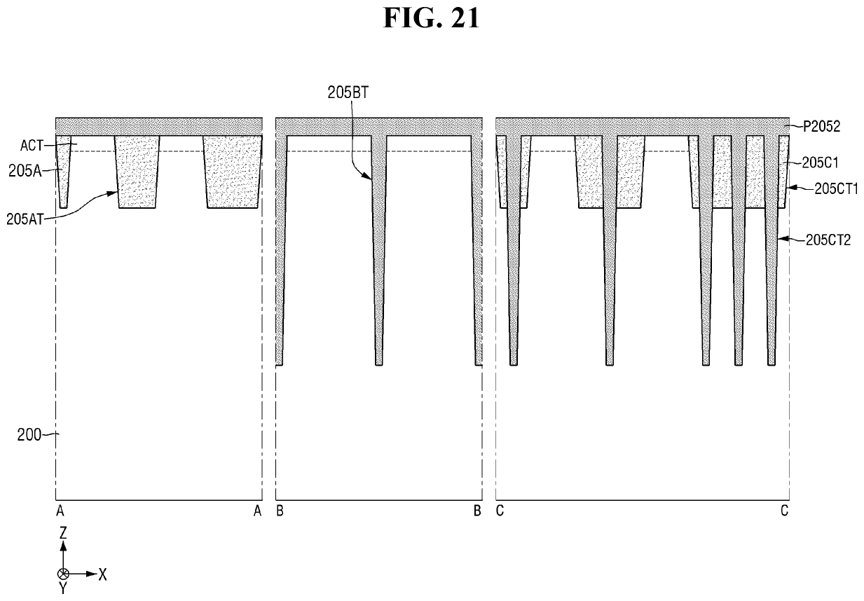

Referring to FIG. 21, a second pre-insulating film P2052 may be formed in the second trench 205BT and the fourth trench 205CT2 to fill each of the second trench 205BT and the fourth trench 205CT2. The second pre-insulating film P2052 may include, for example, at least one of silicon nitride, silicon oxide, and silicon oxynitride. The second pre-insulating film P2052 may be formed by, for example, but is not limited to, an atomic layer deposition (ATOM) process.

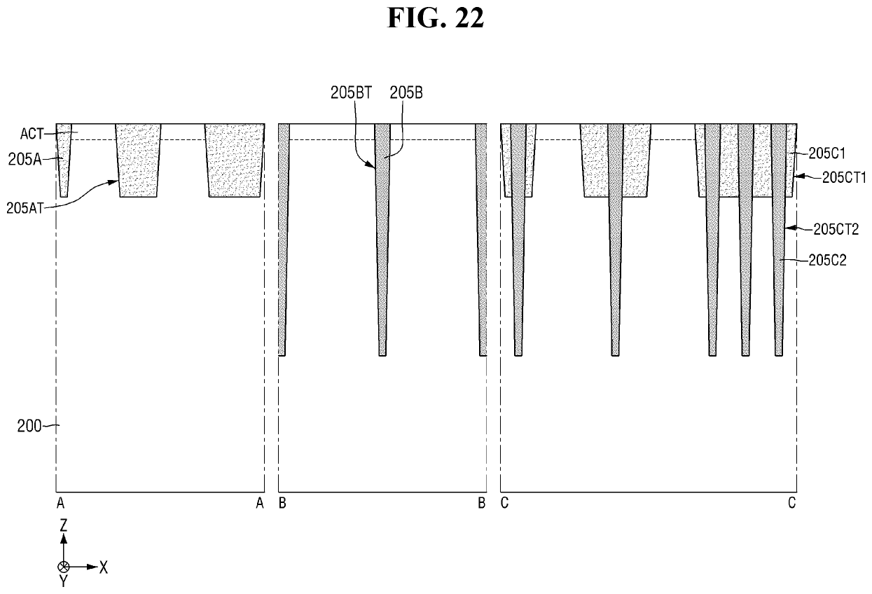

Referring to FIG. 22, at least a part of the second pre-insulating film P2052 in the first to third regions may be removed to form a second element isolation structure 205B and a second element isolation pattern 205C2. In this case, a part of the second pre-insulating film P2052 may be removed so that the upper sides of the second element isolation structure 205B and the second element isolation pattern 205C2 are placed on the same plane, using a chemical mechanical polishing process.

After that, a first gate structure (GS1 of FIG. 6) is formed on the first region, a second gate structure (GS2 of FIG. 7) is formed on the second region, and a third gate structure (GS3 of FIG. 8) may be formed on the third region.

Thereafter, the first to third gate structures (GS1 of FIG. 6, GS2 of FIG. 7, and GS3 of FIG. 8), and the wiring patterns (290 of FIG. 3) and the peripheral circuit interlayer insulating film (210 of FIG. 3) electrically connected to the first to third regions may be formed.

Thereafter, a cell structure (CELL of FIG. 3) including a mold structure (MS of FIG. 3) and a channel structure (CH of FIG. 3) may be formed on the peripheral circuit interlayer insulating film (210 of FIG. 3).

Accordingly, the semiconductor memory device explained using FIGS. 1 to 8 may be formed.

According to some implementations, a third element isolation structure 205C including both a shallow isolation pattern and a deep isolation pattern may be formed in the peripheral circuit region PERI of the semiconductor memory device. Therefore, it is possible to diversify the peripheral circuit elements applicable to the peripheral circuit region PERI.

According to some implementations, the patterning process and the gap-fill process for the shallow isolation pattern and the deep isolation pattern may be dualized to form film qualities included in the shallow isolation pattern and the deep isolation pattern with different film qualities from each other. Accordingly, the difficulty level of the patterning process for forming each element isolation pattern may be reduced, compared to a case where the shallow isolation pattern and the deep isolation pattern are formed at the same time.

According to some implementations, the deep isolation pattern may be formed by the atomic layer deposition process, by forming the deep isolation pattern to have a width of 150 nm or less. Accordingly, it is possible to prevent dislocation caused by a difference in materials between the peripheral circuit board and the element isolation pattern.

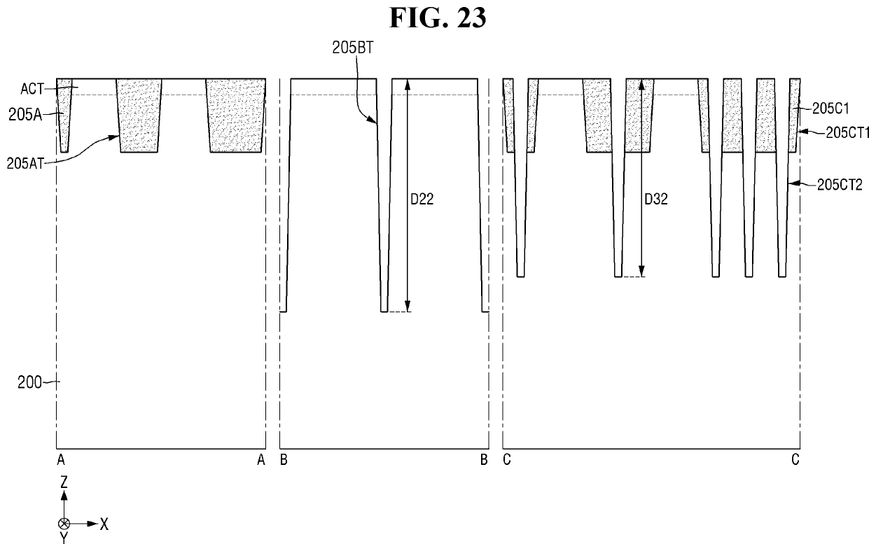

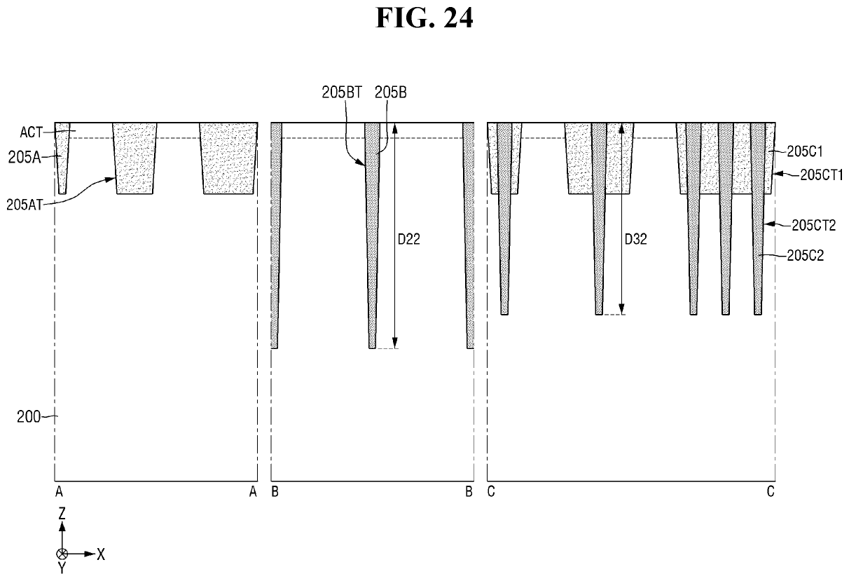

FIGS. 23 to 24 are intermediate stage diagrams for explaining an example method for fabricating a semiconductor memory device. For convenience of explanation, repeated contents of those explained using FIGS. 17 to 22 will be briefly explained or omitted.

Referring to FIG. 23, a fourth depth D32 of the fourth trench 205CT2 may be smaller than a second depth D22 of the second trench 205BT.

The material included in the peripheral circuit board 200 and the material included in the first element isolation pattern 205C1 may be different from each other. For example, the peripheral circuit board 200 may include silicon (Si), and the first element isolation pattern 205C1 may include oxide. In the process of patterning the fourth trench 205CT2 and the second trench 205BT, the depth of the fourth trench 205CT2 may be formed differently from the depth of the second trench 205BT due to a difference in etching rate between the peripheral circuit board 200 and the first element isolation pattern 205C1.

Referring to FIG. 24, a pre-insulating film may be formed in the second trench 205BT and the fourth trench 205CT2 to fill each of the second trench 205BT and the fourth trench 205CT2. The pre-insulating film may include, for example, at least one of silicon nitride, silicon oxide, and silicon oxynitride. The pre-insulating film may be formed by, for example, but is not limited to, an atomic layer deposition process.

Thereafter, at least a part of the pre-insulating film may be removed by a chemical mechanical polishing process to form a second element isolation structure 205B and a second element isolation pattern 205C2. The fourth depth D32 of the second element isolation pattern 205C2 may be smaller than the second depth D22 of the second element isolation structure 205B.

The upper sides of the second element isolation structure 205B and the second element isolation pattern 205C2 may be placed on the same plane, using the chemical mechanical polishing process.

Accordingly, the semiconductor memory device explained using FIG. 9 may be formed.

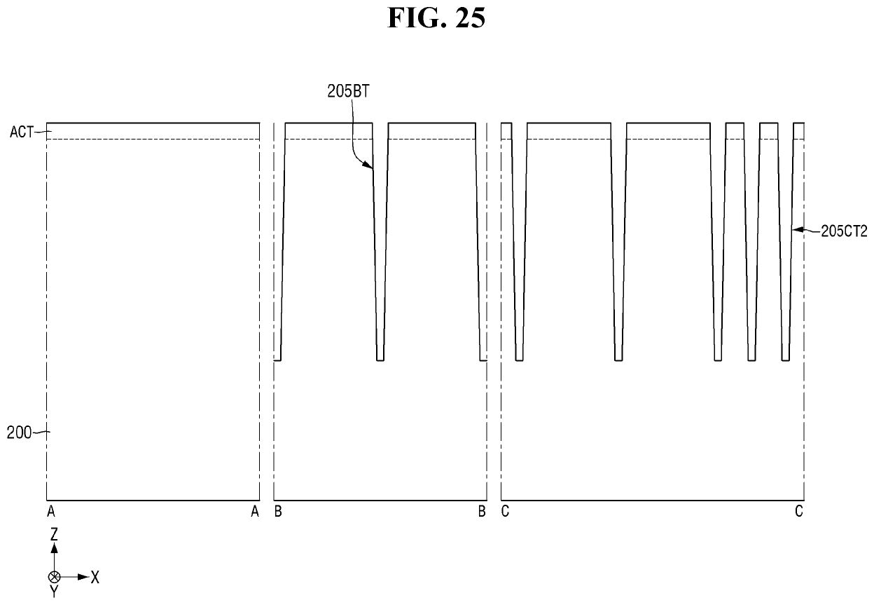

FIGS. 25 to 29 are intermediate stage diagrams for explaining an example method for fabricating a semiconductor memory device. For convenience of explanation, repeated contents of those explained using FIGS. 17 to 24 will be briefly explained or omitted.

Referring to FIG. 25, a peripheral circuit board 200 including first to third regions may be provided. Each of the first to third regions may mean a region in which each of the first to third element isolation structures 205A, 205B, and 205C explained above is formed.

Although not specifically shown, a mask may be formed on the peripheral circuit board 200. The mask may be formed on the second and third regions of the peripheral circuit board 200, and may not be formed on the first region. The second trench 205BT and the fourth trench 205CT2 may be formed in the peripheral circuit board 200, using the mask.

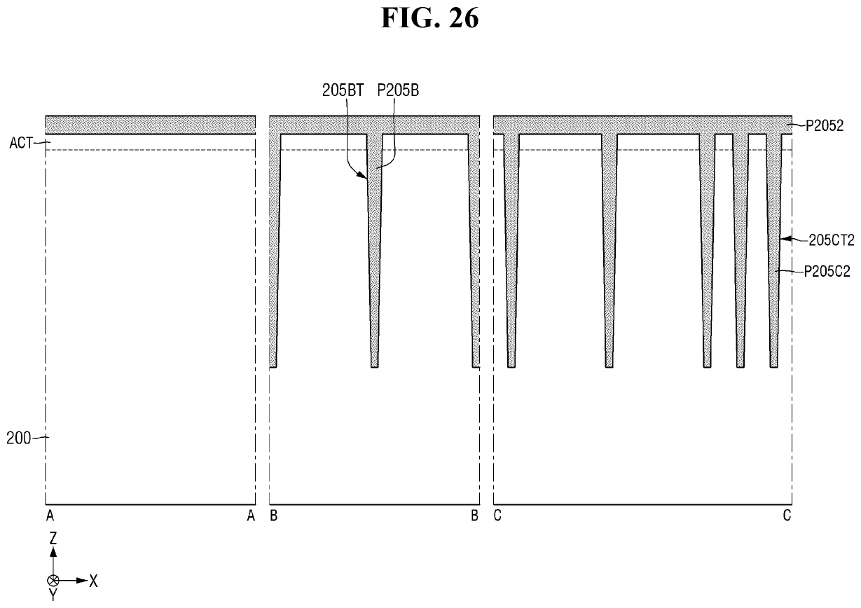

Referring to FIG. 26, a second pre-insulating film P2052 may be formed in the second trench 205BT and the fourth trench 205CT2 to fill each of the second trench 205BT and the fourth trench 205CT2. The second pre-insulating film P2052 may include, for example, at least one of silicon nitride, silicon oxide, and silicon oxynitride. The second pre-insulating film P2052 may be formed by, for example, but is not limited to, the atomic layer deposition process.

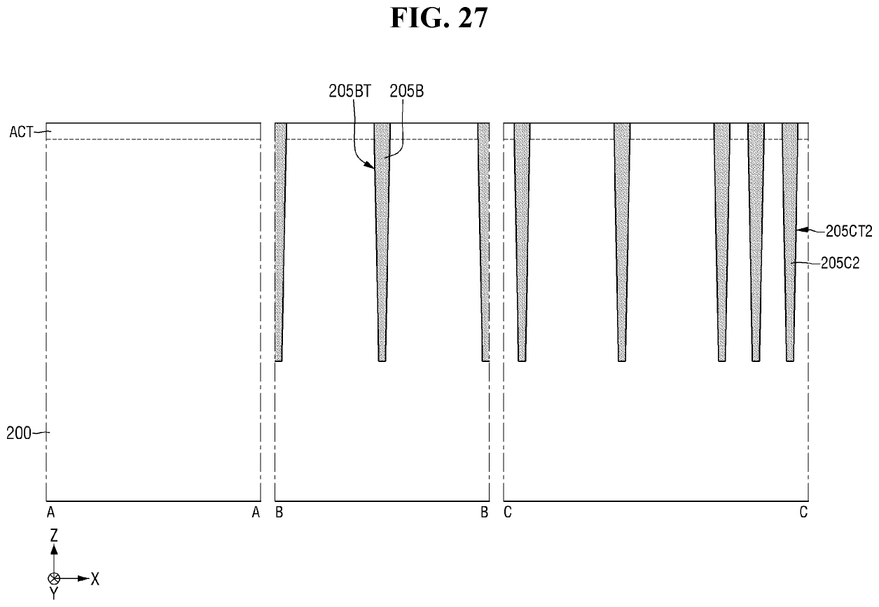

Referring to FIG. 27, at least a part of the second pre-insulating film P2052 of the first to third regions may be removed to form a second element isolation structure 205B and a second element isolation pattern 205C2. In this case, a part of the second pre-insulating film P2052 may be removed so that the upper sides of the second element isolation structure 205B and the second element isolation pattern 205C2 are placed on the same plane, using the chemical mechanical polishing process.

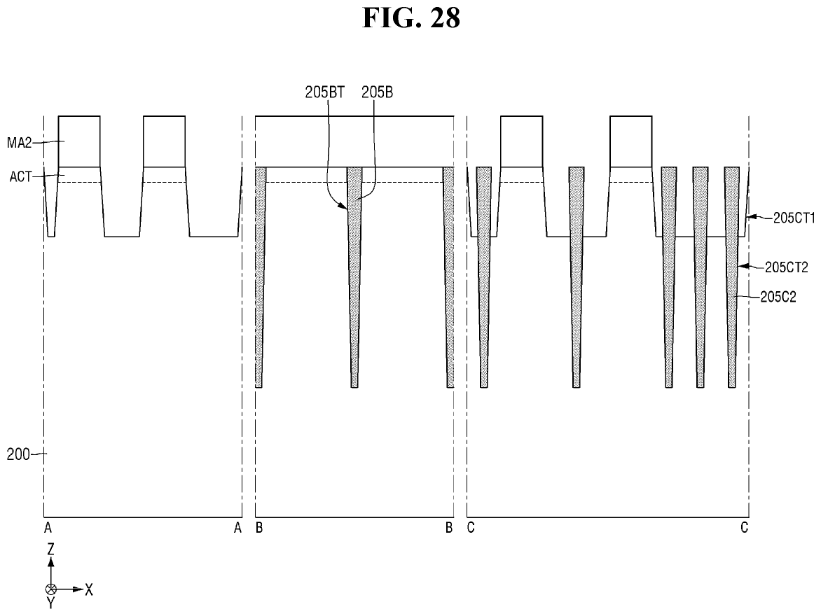

Referring to FIG. 28, a second mask pattern MA2 may be formed in the first to third regions of the peripheral circuit board 200. The second mask pattern MA2 may be formed in the first to third regions, in the region except for the region in which the first trench 205AT and the third trench 205CT1 are formed. The first trench 205AT and the third trench 205CT1 may be formed in the peripheral circuit board 200, using the second mask pattern MA2. Thereafter, the second mask pattern MA2 may be removed.

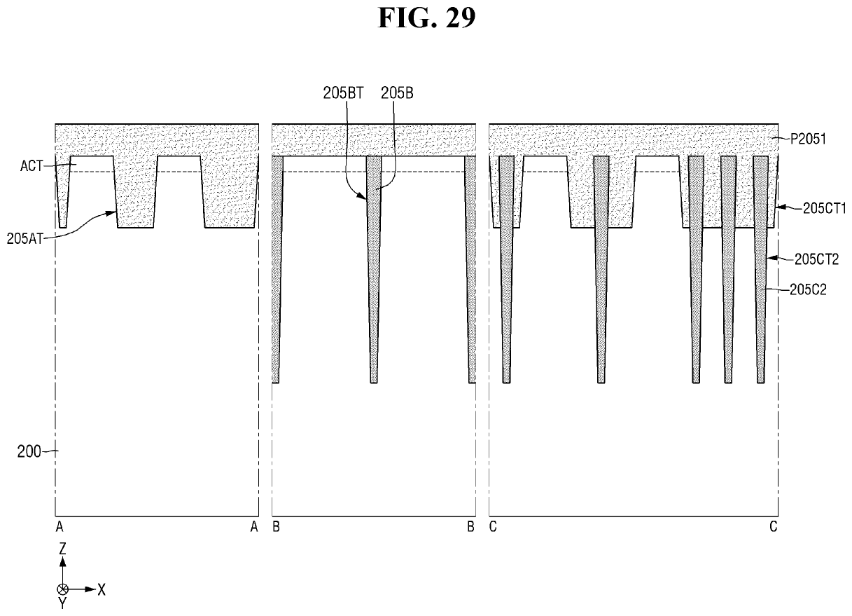

Referring to FIG. 29, a first pre-insulating film P2051 may be formed in the first trench 205AT and the third trench 205CT1 to fill each of the first trench 205AT and the third trench 205CT1. The first pre-insulating film P2051 may include, for example, at least one of silicon nitride, silicon oxide, and silicon oxynitride. The first pre-insulating film P2051 may be formed in a bottom-up manner by, for example, but is not limited to, the chemical vapor deposition process.

Thereafter, at least a part of the first pre-insulating film P2051 of the first to third regions may be removed to form the first element isolation structure 205A and the first element isolation pattern 205C1 as shown in FIG. 22. In this case, a part of the first pre-insulating film P2051 may be removed so that the upper sides of the first element isolation structure 205A and the first element isolation pattern 205C1 are placed on the same plane, using the chemical mechanical polishing process.

The semiconductor memory device explained using FIGS. 1 to 8 may be formed, accordingly.

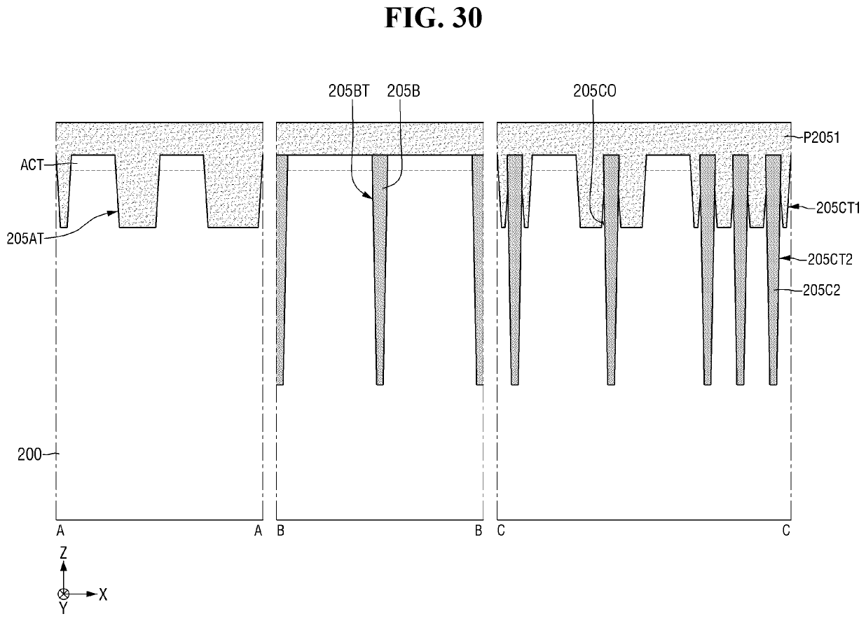

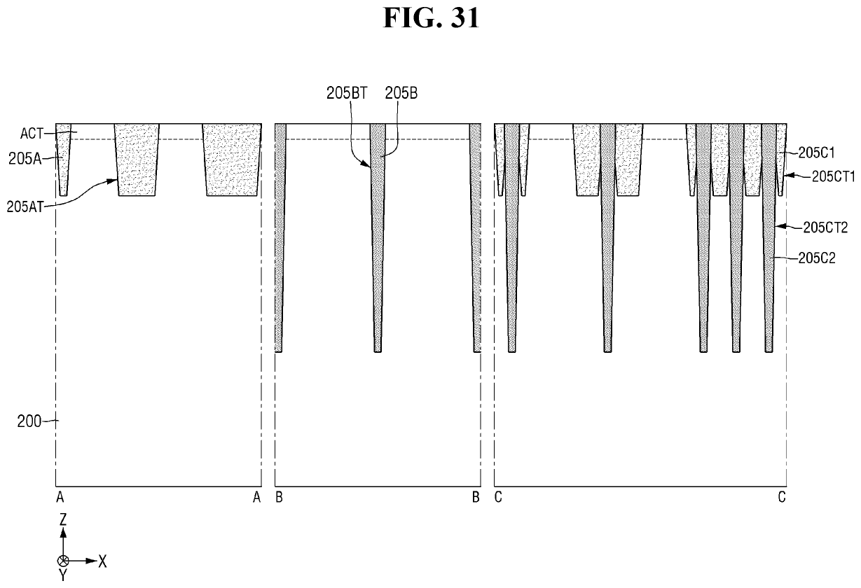

FIGS. 30 to 31 are intermediate stage diagrams for explaining an example method for fabricating a semiconductor memory device. For convenience of explanation, repeated contents of those explained using FIGS. 25 to 29 will be briefly explained or omitted.

Referring to FIGS. 30 and 31, a fence pattern 205CO may be formed in at least a part between the first element isolation pattern 205C1 and the second element isolation pattern 205C2. The fence pattern 205CO may have a shape that is recessed toward the upper side 200_1 of the peripheral circuit board 200 between one side wall of the first element isolation pattern 205C1 and one side wall of the second element isolation pattern 205C2.

When the first element isolation pattern 205C1 is formed after the second element isolation pattern 205C2 is formed, a third trench 205CT1 may be formed, using the etching selectivity of the material included in the peripheral circuit board 200 and the material included in the second element isolation pattern 205C2. For example, the peripheral circuit board 200 may include silicon (Si), and the second element isolation pattern 205C2 may include oxide. In this case, silicon (Si) may be further etched in a region adjacent to the side wall of the second element isolation pattern 205C2. A trench that defines the fence pattern 205CO may be formed, accordingly.

The width of the fence pattern 205CO may decrease toward the upper side 200_1 of the peripheral circuit board 200 on the basis of the first direction X. The fence pattern 205CO may include silicon (Si).

At least a part of the first pre-insulating film P2051 of the first to third regions is removed, and the first element isolation structure 205A and the first element isolation pattern 205C1 may be formed. In this case, a part of the first pre-insulating film P2051 may be removed so that the upper sides of the first element isolation structure 205A and the first element isolation pattern 205C1 are placed on the same plane, using the chemical mechanical polishing process.

The semiconductor memory device explained using FIG. 11 may be formed, accordingly.

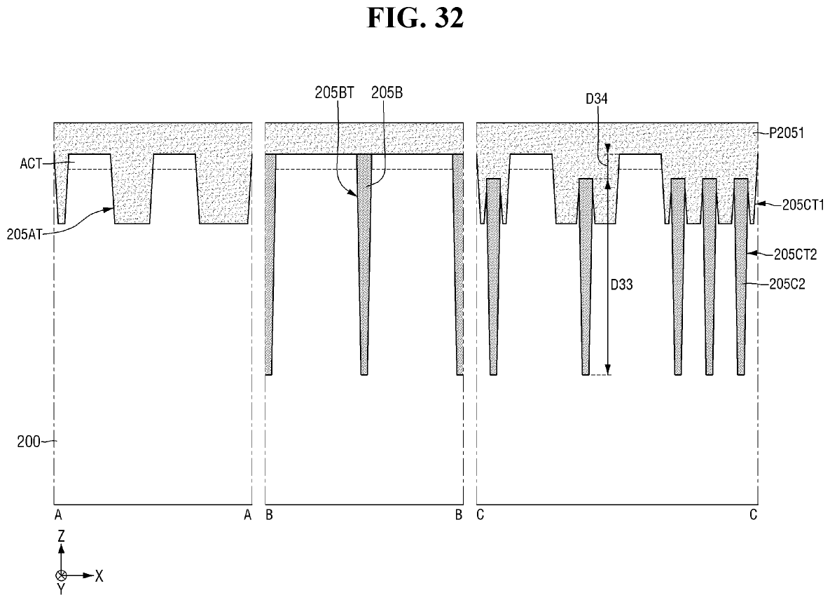

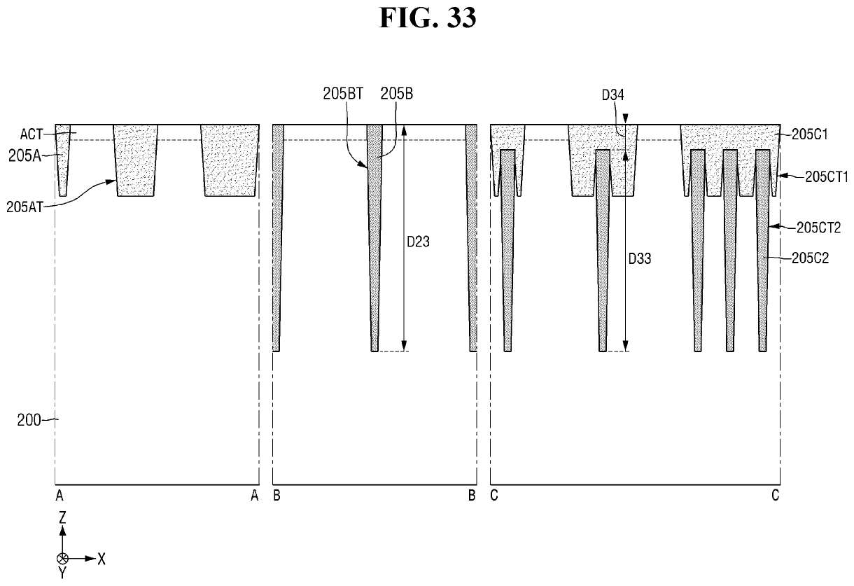

FIGS. 32 and 33 are intermediate stage diagrams for explaining an example method for fabricating a semiconductor memory device. For convenience of explanation, repeated contents of those explained using FIGS. 30 to 31 will be briefly explained or omitted.

Referring to FIGS. 32 and 33, the upper side of the first element isolation pattern 205C1 may be placed to be closer to the upper side 200_1 of the peripheral circuit board 200 than the upper side of the second element isolation pattern 205C2. The upper side of the second element isolation structure 205B may be placed to be closer to the upper side 200_1 of the peripheral circuit board 200 than the upper side of the second element isolation pattern 205C2. A depth D33 of the fourth trench 205CT2 may be smaller than the depth D23 of the second trench 205BT.

The upper side of the peripheral circuit board 200 and the upper side of the second element isolation pattern 205C2 may be spaced apart by a first distance D34, and the upper side of the second element isolation pattern 205C2 and the bottom side of the fourth trench 205CT2 may be spaced apart by a second distance D33.

At least a part of the first pre-insulating film P2051 of the first to third regions is removed, and the first element isolation structure 205A and the first element isolation pattern 205C1 may be formed. In this case, a part of the first pre-insulating film P2051 may be removed so that the upper sides of the first element isolation structure 205A and the first element isolation pattern 205C1 are placed on the same plane, using the chemical mechanical polishing process.

The semiconductor memory device explained using FIG. 12 may be formed, accordingly.

An electronic system including the semiconductor memory device according to some implementations of the present disclosure will be explained below with reference to FIGS. 1 to 8 and 34 to 36.

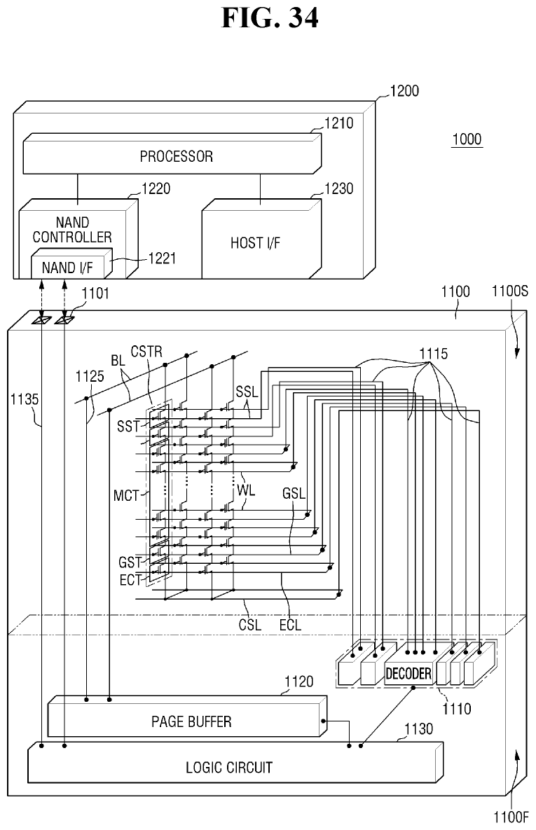

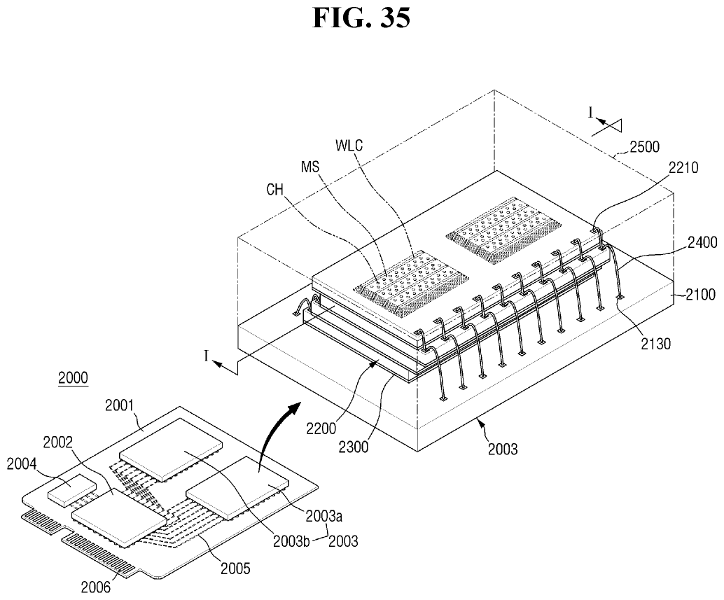

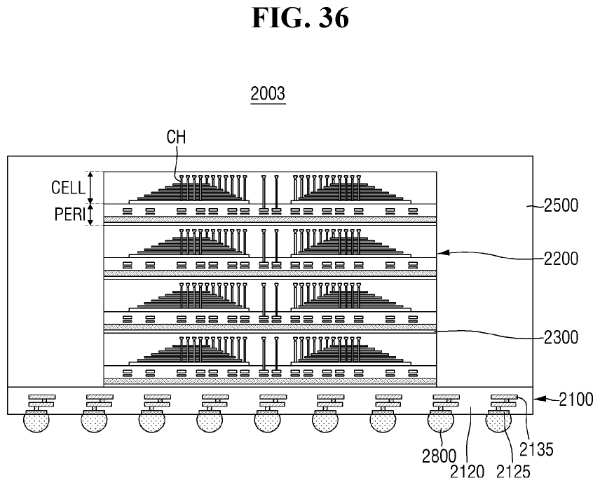

FIG. 34 is an example block diagram for explaining an electronic system. FIG. 35 is an example perspective view for explaining an electronic system. FIG. 36 is an example schematic cross-sectional view taken along line I-I of FIG. 35.

Referring to FIG. 34, an electronic system 1000 may include a semiconductor memory device 1100, and a controller 1200 that is electrically connected to the semiconductor memory device 1100. The electronic system 1000 may be a storage device that includes one or multiple semiconductor memory devices 1100, or an electronic device that includes the storage device. For example, the electronic system 1000 may be an SSD device (solid state drive device), a USB (Universal Serial Bus), a computing system, a medical device or a communication device that includes one or multiple semiconductor memory devices 1100.

The semiconductor memory device 1100 may be, for example, a NAND flash memory device, and may be, for example, the semiconductor memory device explained above using FIGS. 1 to 15. The semiconductor memory device 1100 may include a first structure 1100F, and a second structure 1100S on the first structure 1100F.

The first structure 1100F may be a peripheral circuit structure that includes a decoder circuit 1110 (e.g., a row decoder 33 of FIG. 1), a page buffer 1120 (e.g., the page buffer 35 of FIG. 1), and a logic circuit 1130 (e.g., the control logic 37 of FIG. 1).

The second structure 1100S may include the common source line CSL, the plurality of bit lines BL, and the plurality of cell strings CSTR explained above using FIG. 2. The cell strings CSTR may be connected to the decoder circuit 1110 through the word line WL, at least one string selection line SSL, and at least one ground selection line GSL. Additionally, the cell strings CSTR may be connected to the page buffer 1120 through the bit lines BL.

In some implementations, the common source line CSL and the cell strings CSTR may be electrically connected to the decoder circuit 1110 through a first connection wiring 1115 extending from the first structure 1100F to the second structure 1100S.

In some implementations, the bit lines BL may be electrically connected to the page buffer 1120 through second connection wirings 1125 that extend from the first structure 1100F to the second structure 1100S. The page buffer 1120 may be the peripheral circuit element PT explained using FIGS. 1 to 15.

The semiconductor memory device 1100 may communicate with the controller 1200 through an I/O pad 1101 that is electrically connected to the logic circuit 1130 (e.g., the control logic 37 of FIG. 1). The I/O pad 1101 may be electrically connected to the logic circuit 1130 through an I/O connection wiring 1135 extending from the inside of the first structure 1100F to the second structure 1100S.

The controller 1200 may include a processor 1210, a NAND controller 1220, and a host interface 1230. In some implementations, the electronic system 1000 may include a plurality of semiconductor memory devices 1100, and in this case, the controller 1200 may control the plurality of semiconductor memory devices 1100.

The processor 1210 may control the overall operation of the electronic system 1000, including the controller 1200. The processor 1210 may operate according to a predetermined firmware, and may control the NAND controller 1220 to access the semiconductor memory device 1100. The NAND controller 1220 may include a NAND interface 1221 that processes communication with the semiconductor memory device 1100. Control command for controlling the semiconductor memory device 1100, data to be recorded in the memory cell transistors MCT of the semiconductor memory device 1100, data to be read from the memory cell transistors MCT of the semiconductor memory device 1100, and the like may be transmitted through the NAND interface 1221. The host interface 1230 may provide a communication function between the electronic system 1000 and an external host. When receiving the control command from the external host through the host interface 1230, the processor 1210 may control the semiconductor memory device 1100 in response to the control command.

Referring to FIGS. 34 to 36, the electronic system may include a main board 2001, a main controller 2002 mounted on the main board 2001, one or more semiconductor packages 2003, and a DRAM 2004. The semiconductor package 2003 and the DRAM 2004 may be connected to the main controller 2002 by wiring patterns 2005 formed on the main board 2001.

The main board 2001 may include a connector 2006 including a plurality of pins coupled to an external host. In the connector 2006, the number and placement of the plurality of pins may vary depending on the communication interface between the electronic system 2000 and the external host. In some implementations, the electronic system 2000 may communicate with the external host according to any one of interfaces such as M-Phy for a USB (Universal Serial Bus), a PCI-Express (Peripheral Component Interconnect Express), a SATA (Serial Advanced Technology Attachment), and a UFS (Universal Flash Storage). In some implementations, the electronic system 2000 may operate by power supplied from the external host through the connector 2006. The electronic system 2000 may further include a PMIC (Power Management Integrated Circuit) that distributes the power supplied from the external host to the main controller 2002 and the semiconductor package 2003.

The main controller 2002 may record data in the semiconductor package 2003 or read data from the semiconductor package 2003, and may improve the operating speed of the electronic system 2000.

The DRAM 2004 may be a buffer memory for relieving a speed difference between the semiconductor package 2003, which is a data storage space, and the external host. The DRAM 2004 included in the electronic system 2000 may also operate as a kind of cache memory, and may also provide a space for temporarily storing data in the control operation on the semiconductor package 2003. When the DRAM 2004 is included in the electronic system 2000, the main controller 2002 may further include a DRAM controller for controlling the DRAM 2004, in addition to a NAND controller for controlling the semiconductor package 2003.

The semiconductor package 2003 may include a first semiconductor package 2003a and a second semiconductor package 2003b that are spaced apart from each other. The first semiconductor package 2003a and the second semiconductor package 2003b may each be a semiconductor package that includes a plurality of semiconductor chips 2200. The first semiconductor package 2003a and the second semiconductor package 2003b may each include a package substrate 2100, semiconductor chips 2200 on the package substrate 2100, adhesive layers 2300 placed on the lower sides of each of the package chips 220, a connecting structure 2400 for electrically connecting the semiconductor chips 2200 and the package substrate 2100, and a molding layer 2500 that covers the semiconductor chips 2200 and the connecting structure 2400 on the package substrate 2100.

The package substrate 2100 may be a printed circuit board that includes package upper pads 2130. Each semiconductor chip 2200 may include an I/O pad 2210. The I/O pad 2210 may correspond to the I/O pad 1101 of FIG. 34.

In some implementations, the connecting structure 2400 may be a bonding wire that electrically connects the I/O pad 1101 and the package upper pads 2130. Therefore, in each of the first semiconductor package 2003a and the second semiconductor package 2003b, the semiconductor chips 2200 may be electrically connected to each other in a bonding wire manner, and may be electrically connected to the package upper pads 2130 of the package substrate 2100. In some implementations, in each of the first semiconductor package 2003a and the second semiconductor package 2003b, the semiconductor chips 2200 may be electrically connected to each other by a connecting structure including a through electrode (Through Silicon Via, TSV), instead of the connecting structure 2400 of a bonding wire type.

In some implementations, the main controller 2002 and the semiconductor chips 2200 may also be included in a single package. In some implementations, the main controller 2002 and the semiconductor chips 2200 are mounted on a separate interposer substrate different from the main board 2001, and the main controller 2002 and the semiconductor chips 2200 may also be connected to each other by the wiring formed on the interposer substrate.

In some implementations, the package substrate 2100 may be a printed circuit board. The package substrate 2100 may include a package substrate body part 2120, package upper pads 2130 placed on an upper side of the package substrate body part 2120, lower pads 2125 placed on a lower side of the package substrate body part 2120 or exposed through the lower side, and inner wirings 2135 that electrically connect the upper pads 2130 and the lower pads 2125 inside the package substrate body part 2120. The upper pads 2130 may be electrically connected to the connecting structures 2400. The lower pads 2125 may be connected to the wiring patterns 2005 of the main board 2001 of the electronic system 2000 through conductive connections 2800, as in FIG. 35.

Referring to FIGS. 35 and 36, in the electronic system, each of the semiconductor chips 2200 may include the semiconductor memory device explained above using FIGS. 1 to 15. For example, each of the semiconductor chips 2200 may include a peripheral circuit structure PERI and a cell structure CELL stacked on the peripheral circuit structure PERI. As an example, the peripheral circuit structure PERI may include the peripheral circuit board 200, and the peripheral circuit element PT explained above using FIGS. 1 to 15. Further, as an example, the cell structure CELL may include the cell substrate 100, the mold structure MS, the channel structure CH, the word line cutting structure WLC, and the bit line BL explained above using FIGS. 3 and 4.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although the implementations of the present disclosure have been explained above with reference to the accompanying drawings, the present disclosure is not limited to the above implementations, and may be fabricated in various different forms. Those skilled in the art will appreciate that the present disclosure may be embodied in other specific forms without changing the technical spirit or essential features of the present disclosure. Accordingly, the above-described implementations should be understood in all respects as illustrative and not restrictive.

What is claimed is:

1. A semiconductor memory device comprising:
a cell region; and
a peripheral circuit region electrically connected with the cell region,
wherein the cell region includes
a plurality of gate electrodes spaced apart from each other, the plurality of gate electrodes stacked in a vertical direction, and
a channel structure extending through the plurality of gate electrodes in the vertical direction,
wherein the peripheral circuit region includes
a substrate,
a first element isolation structure defining a first active region in the substrate, the first element isolation structure extending to a first depth,
a first gate structure on the first active region,
a second element isolation structure defining a second active region in the substrate, the second element isolation structure extending to a second depth larger than the first depth,
a second gate structure on the second active region,
a third element isolation structure defining a third active region in the substrate, the third element isolation structure including a first element isolation pattern and a second element isolation pattern, the first element isolation pattern extending to a third depth, and the second element isolation pattern extending to a fourth depth larger than the third depth inside the first element isolation pattern, and
a third gate structure on the third active region,
wherein the first element isolation pattern and the second element isolation pattern include different materials from each other.

2. The semiconductor memory device of claim 1,
wherein the first depth of the first element isolation structure is the same as the third depth of the first element isolation pattern.

3. The semiconductor memory device of claim 1,
wherein the fourth depth of the second element isolation pattern is smaller than or equal to the second depth of the second element isolation structure.

4. The semiconductor memory device of claim 1,
wherein a width of the first element isolation structure is larger than a width of the second element isolation structure.

5. The semiconductor memory device of claim 1,
wherein a width of the first element isolation pattern is larger than a width of the second element isolation pattern.

6. The semiconductor memory device of claim 1,
wherein a width of the second element isolation structure is equal to a width of the second element isolation pattern.

7. The semiconductor memory device of claim 1,
wherein the semiconductor memory device comprises a plurality of first element isolation structures and a plurality of first element isolation patterns, the plurality of first element isolation structures having different widths from each other, and the plurality of first element isolation patterns having different widths from each other.

8. The semiconductor memory device of claim 1,
wherein the first element isolation structure includes a different material from the second element isolation structure.

9. The semiconductor memory device of claim 1,
wherein the substrate includes a fence pattern in at least a part between the first element isolation pattern and the second element isolation pattern, and
wherein a width of the fence pattern decreases toward an upper side of the substrate.

10. The semiconductor memory device of claim 9,
wherein an upper side of the first element isolation pattern is closer to the upper side of the substrate than an upper side of the second element isolation pattern.

11. A semiconductor memory device comprising:
a cell region; and
a peripheral circuit region electrically connected with the cell region,
wherein the cell region includes
a plurality of gate electrodes spaced apart from each other, the plurality of gate electrodes stacked in a vertical direction, and
a channel structure extending through the plurality of gate electrodes in the vertical direction,
wherein the peripheral circuit region includes
a substrate including a first side and a second side, the first side and the second side opposite to each other,
a first element isolation structure defining a first active region in the substrate, the first element isolation structure in a first trench having a first width,
a first gate structure extending in a direction intersecting the first active region, the first gate structure being on the first active region,
a second element isolation structure defining a second active region in the substrate, the second element isolation structure in a second trench having a second width, the second width being smaller than the first width,
a second gate structure extending in a direction intersecting the second active region, the second gate structure being on the second active region,
a third element isolation structure defining a third active region in the substrate, the third element isolation structure in a third trench having a third width and a fourth trench having a fourth width, the fourth width being smaller than the third width, and
a third gate structure extending in a direction intersecting the third active region, the third gate structure being on the third active region,
wherein a bottom side of the fourth trench is closer to the first side of the substrate than a bottom side of the second trench.

12. The semiconductor memory device of claim 11,
wherein a depth of the first trench is the same as a depth of the third trench.

13. The semiconductor memory device of claim 11,
wherein a depth of the fourth trench is smaller than a depth of the second trench.

14. The semiconductor memory device of claim 11,
wherein the third element isolation structure comprises
a first element isolation pattern in the third trench, and
a second element isolation pattern in the fourth trench,
wherein the first element isolation pattern and the second element isolation pattern include different materials from each other.

15. The semiconductor memory device of claim 14,
wherein the semiconductor memory device comprises a plurality of first element isolation patterns and a plurality of second element isolation patterns, the plurality of first element isolation patterns having different widths from each other, and
wherein the plurality of second element isolation patterns have the same width.

16. The semiconductor memory device of claim 14,
wherein a void is in at least a part of the first element isolation structure and at least a part of the first element isolation pattern, and
wherein a seam is in at least a part of the second element isolation structure and at least a part of the second element isolation pattern.

17. The semiconductor memory device of claim 14,
wherein a width of the second element isolation structure is equal to a width of the second element isolation pattern.

18. The semiconductor memory device of claim 17,
wherein the width of the second element isolation structure is smaller than or equal to 150 nm, and the width of the second element isolation pattern is smaller than or equal to 150 nm.

19. A semiconductor memory device comprising:
a cell structure; and
a peripheral circuit structure electrically connected with the cell structure,
wherein the cell structure includes
a plurality of gate electrodes spaced apart from each other, the plurality of gate electrodes stacked in a vertical direction;
a channel structure extending through the plurality of gate electrodes in the vertical direction; and
a bit line connected with the channel structure,
wherein the peripheral circuit structure includes
a substrate including a first region and a second region, the first region including a first peripheral circuit element, the second region including a second peripheral circuit element, the first peripheral circuit element and the second peripheral circuit element being different from each other,
a first element isolation structure in the first region of the substrate, the first element isolation structure extending to a first depth,
a second element isolation structure in the second region of the substrate, the second element isolation structure extending to a second depth larger than the first depth, and
a third element isolation structure in at least one of the first region or the second region of the substrate, the third element isolation structure including a first element isolation pattern and a second element isolation pattern, the first element isolation pattern extending to a third depth, and the second element isolation pattern extending to a fourth depth larger than the third depth inside the first element isolation pattern,
wherein a first width of the first element isolation structure is greater than a second width of the second element isolation structure,
wherein a third width of the first element isolation pattern is greater than a fourth width of the second element isolation pattern,
wherein the second width of the second element isolation structure is the same as the fourth width of the second element isolation pattern, and
wherein the first element isolation pattern and the second element isolation pattern include different materials from each other.

20. The semiconductor memory device of claim 19,
wherein the fourth depth of the second element isolation pattern is smaller than or equal to the second depth of the second element isolation structure.
